(19) United States
(12) Patent Application Publication
(10) Pub. No.: US 2023/0223251 A1
(43) Pub. Date: Jul. 13, 2023

(54) METHOD OF MANUFACTURING SEMICONDUCTOR DEVICE, SEMICONDUCTOR MANUFACTURING DEVICE, AND SYSTEM

(71) Applicant: Tokyo Electron Limited, Tokyo (JP)

(72) Inventors: Hirokazu UEDA, Yamanashi (JP); Mitsuaki IWASHITA, Yamanashi (JP); Naoki UMESHITA, Tokyo (JP); Yoji IIZUKA, Tokyo (JP); Takashi HAYAKAWA, Tokyo (JP); Kenji SEKIGUCHI, Yamanashi (JP); Koji AKIYAMA, Yamanashi (JP)

(21) Appl. No.: 17/997,158

(22) PCT Filed: Apr. 20, 2021
(86) PCT No.: PCT/JP2021/016028

§ 371 Date: Oct. 26, 2022

(30) Foreign Application Priority Data
Apr. 28, 2020 (JP) 2020-079705
Dec. 22, 2020 (JP) 2020-212880

(51) Int. Cl. H01L 21/02; H01L 21/67; H01L 21/285

(52) U.S. Cl. CPC H01L 21/02307; H01L 21/6715; H01L 21/28556; H01L 21/0228

(57) ABSTRACT

In a method of manufacturing a semiconductor device, the method includes: applying a liquid material containing an ionic liquid on a substrate to form a protective film; transferring at an atmosphere the substrate on which the protective film is formed; and removing the protective film from the substrate that has been transferred at the atmosphere.

### TECHNICAL FIELD

The present invention relates to a method of manufacturing a semiconductor device, a semiconductor manufacturing device, and a system.

### BACKGROUND ART

A technique is known in which active gas species of NF₃ gas are reacted with a natural oxide film on a surface of a semiconductor wafer to form a protective film, and then the semiconductor wafer is heated to sublimate the protective film to remove the natural oxide film in a fine recess or the like (see, for example, Patent Literature 1).

### CITATION LIST

### Patent Literature

[PTL 1]
Japanese Laid-Open Patent Publication No. H10-335316

### SUMMARY OF INVENTION

### Technical Problem

The present disclosure provides a technique that can prevent formation of a natural oxide film on a surface of a substrate.

### Solution to Problem

One aspect of the present disclosure is: a method of manufacturing a semiconductor device, the method including: applying a liquid material containing an ionic liquid on a substrate to form a protective film; transferring at an atmosphere the substrate on which the protective film is formed; and removing the protective film from the substrate that has been transferred at the atmosphere.

### Advantageous Effects of Invention

According to the present disclosure, it is possible to prevent formation of a natural oxide film on a surface of a substrate.

### BRIEF DESCRIPTION OF THE DRAWINGS

FIG. 1 is a diagram illustrating an example of a method of manufacturing a semiconductor device according to a first embodiment;

FIG. 2A is a process cross-sectional diagram illustrating an example of the method of manufacturing a semiconductor device according to the first embodiment;

FIG. 2B is a process cross-sectional diagram illustrating an example of the method of manufacturing a semiconductor device according to the first embodiment;

FIG. 2C is a process cross-sectional diagram illustrating an example of the method of manufacturing a semiconductor device according to the first embodiment;

FIG. 2D is a process cross-sectional diagram illustrating an example of the method of manufacturing a semiconductor device according to the first embodiment;

FIG. 2E is a process cross-sectional diagram illustrating an example of the method of manufacturing a semiconductor device according to the first embodiment;

FIG. 3 is a schematic diagram illustrating an example of a vacuum deposition device;

FIG. 4 is a schematic diagram illustrating an example of a spin coater;

FIG. 5 is a schematic diagram illustrating an example of a slit coater;

FIG. 6 is a schematic diagram illustrating an example of the slit coater;

FIG. 7 is a schematic diagram illustrating another example of the slit coater;

FIG. 8 is a schematic diagram illustrating an example of a peeling device;

FIG. 9 is a diagram for explaining a stage of the peeling device of FIG. 7;

FIG. 10 is a diagram for explaining the stage of the peeling device of FIG. 7;

FIG. 11 is a diagram illustrating an example of a method of manufacturing a semiconductor device according to a second embodiment;

FIG. 12 is a schematic diagram illustrating an example of a vacuum slit coater;

FIG. 13 is a diagram illustrating an example of a method of manufacturing a semiconductor device according to a third embodiment;

FIG. 14 is a diagram illustrating an example of a method of manufacturing a semiconductor device according to a fourth embodiment;

FIG. 15A is a process cross-sectional diagram illustrating an example of a method of embedding Cu in a via formed in a laminated film;

FIG. 15B is a process cross-sectional diagram illustrating an example of a method of embedding Cu in a via formed in a laminated film;

FIG. 15C is a process cross-sectional diagram illustrating an example of a method of embedding Cu in a via formed in a laminated film;

FIG. 15D is a process cross-sectional diagram illustrating an example of a method of embedding Cu in a via formed in a laminated film;

FIG. 15E is a process cross-sectional diagram illustrating an example of a method of embedding Cu in a via formed in a laminated film;

FIG. 15F is a process cross-sectional diagram illustrating an example of a method of embedding Cu in a via formed in a laminated film;

FIG. 16 is a schematic diagram illustrating a slit coater according to a first modification;

FIG. 17 is a diagram illustrating an example of operation of the slit coater according to the first modification;

FIG. 18 is a diagram illustrating another example of operation of the slit coater according to the first modification;

FIG. 19 is a diagram for explaining a mechanism for inhibiting contact between an ionic liquid and a cleaning liquid;

FIG. 20 is a diagram for explaining a mechanism for preventing contact between an ionic liquid and a cleaning liquid;

FIG. 21 is a schematic diagram illustrating a slit coater according to a second modification;

FIG. 22 is an electrical circuit diagram for explaining a stage grounding circuit;

FIG. 23 is a schematic diagram illustrating a slit coater according to a third modification;

FIG. 24 is an electrical circuit diagram for explaining an outer skin grounding circuit;

FIG. 25 is a schematic diagram illustrating a slit coater according to a fourth modification;

FIG. 26 is a diagram illustrating an example of operation of the slit coater according to the fourth modification;

FIG. 27 is a diagram illustrating another example of operation of the slit coater according to the fourth modification;

FIG. 28A is a diagram illustrating an application example of the slit coater according to the fourth modification;

FIG. 28B is a diagram illustrating an application example of the slit coater according to the fourth modification;

FIG. 28C is a diagram illustrating an application example of the slit coater according to the fourth modification;

FIG. 29 is a schematic diagram illustrating a slit coater according to a fifth modification;

FIG. 30 is a diagram illustrating an example of operation of the slit coater according to the fifth modification; and

FIG. 31 is a diagram illustrating an example of operation of the slit coater according to the fifth modification.

### DESCRIPTION OF EMBODIMENTS

In the following, non-limiting exemplary embodiments of the present disclosure will be described with reference to the accompanying drawings. In all the accompanying drawings, the same or corresponding members or parts are denoted by the same or corresponding reference numerals, and overlapping descriptions are omitted.

### First Embodiment

### (Method of Manufacturing Semiconductor Device)

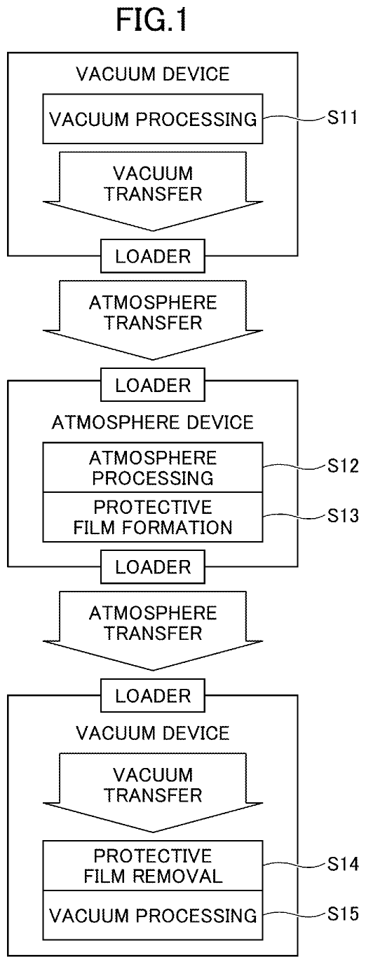

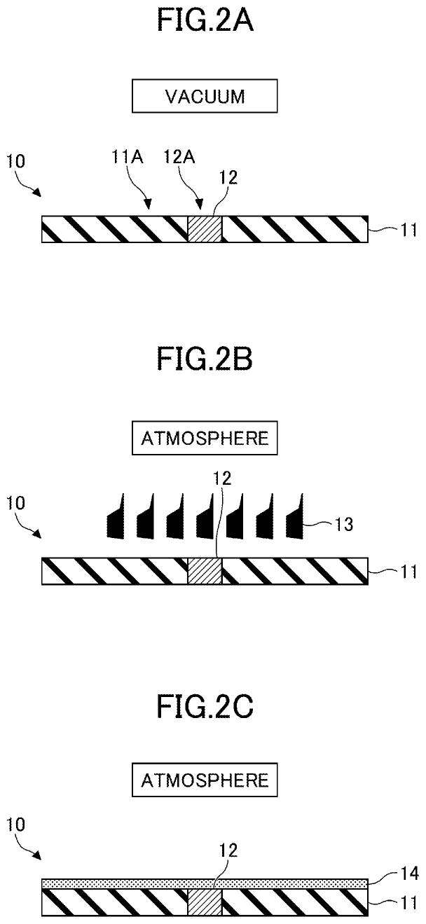

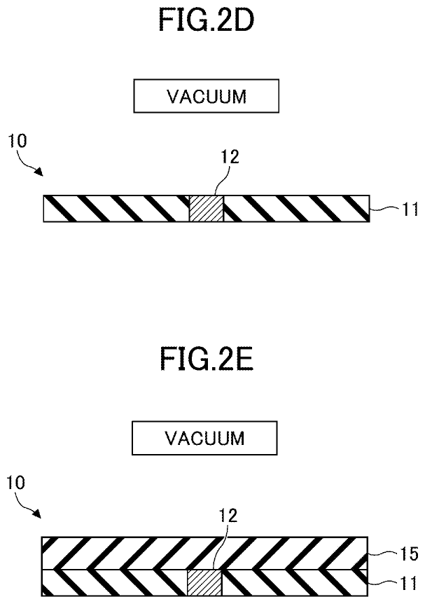

Referring to FIG. 1, an example of a method of manufacturing a semiconductor device according to a first embodiment will be described. FIG. 1 is a diagram illustrating an example of the method of manufacturing a semiconductor device according to the first embodiment. FIGS. 2A to 2E are process cross-sectional diagrams illustrating examples of the method of manufacturing a semiconductor device according to the first embodiment.

The method of manufacturing a semiconductor device according to the first embodiment includes a vacuum processing step S11, an atmosphere processing step S12, a protective film formation step S13, a protective film removal step S14, and a vacuum processing step S15. The vacuum processing step S11, the protective film removal step S14, and the vacuum processing step S15 are performed in a vacuum, and the atmosphere processing step S12 and the protective film formation step S13 are performed at an atmosphere. The term “atmosphere” as used herein means that the process is performed in a state of approximately 1 atm, and the environment during the process may be an inert gas such as a rare gas or N₂ gas.

The vacuum processing step S11 is a step of performing various types of vacuum processing on a substrate in a vacuum device. Examples of the various types of vacuum processing include, but are not limited to, deposition processing, etching processing, chemical oxide removal (COR) processing, and heat processing. The COR processing includes, for example, a step of supplying a mixed gas containing a gas containing a halogen element and a basic gas to a substrate to transform the oxide to generate a reaction product and a step of removing the reaction product. In the present embodiment, the various types of vacuum processing may be a processing for providing, by depositing an insulating film 11 and a conductive film 12, a substrate 10 including a region 11A where an insulating material is exposed and a region 12A where a conductive material is exposed, as illustrated in FIG. 2A, for example. Examples of the insulating material include, but are not limited to, a low dielectric constant film (low-k film). Examples of the conductive material include, but are not limited to, copper (Cu), ruthenium (Ru), cobalt (Co), polysilicon (Poly-Si), and tungsten (W). After being subjected to the various types of vacuum processing in the vacuum device, the substrate is carried out of the vacuum device into the atmosphere via the loader of the vacuum device, transferred at the atmosphere by the transfer device, and then carried in the atmosphere device via the loader of the atmosphere device.

The atmosphere processing step S12 is performed after the vacuum processing step S11, and is a process in which various types of atmosphere processing are performed on the substrate in the atmosphere device. The various types of atmosphere processing include, but are not limited to, wet processing, atmospheric pressure deposition processing, and plating. In the present embodiment, the various types of atmosphere processing may be wet processing that supply a chemical solution 13 containing hydrogen fluoride (HF) to a substrate 10 at the atmosphere to remove an oxide (for example, a natural oxide film) on the surface of the substrate 10, for example, as illustrated in FIG. 2B. Examples of the chemical solution 13 containing HF include, but are not limited to, diluted hydrofluoric acid (DHF). Examples of a method for supplying the chemical solution 13 containing HF to the substrate 10 include, but are not limited to, a spin-coating method and a slit-coating method.

The protective film formation step S13 is performed after the atmosphere processing step S12, and is a step of applying a liquid material containing an ionic liquid to the substrate in an atmosphere device to form a protective film on a surface of the substrate. The protective film formation step S13 is performed in order to protect the surface of the substrate from contamination of the clean surface with impurities such as oxygen (O), water (H₂O), organic matter, and the like, and to prevent the formation of the natural oxide film. Therefore, it is preferable that the protective film formation step S13 is performed continuously after the atmosphere processing step S12. In the present embodiment, as illustrated in FIG. 1, the protective film formation step S13 is continuously performed after the atmosphere processing step S12 in the same atmosphere device as the device for performing the atmosphere processing step S12. According to the present embodiment, in the protective film formation step S13, for example, as illustrated in FIG. 2C, the liquid material containing the ionic liquid is applied on the substrate 10 on which the oxide is removed by wet processing in the atmosphere processing step S12 to form a protective film 14 on the surface of the substrate 10. Therefore, because the surface of the substrate 10 is covered with the protective film 14, it is possible to reduce the adsorption of impurities on the surface of the substrate 10. The protective film 14 formed of the liquid material containing the ionic liquid has a property of not evaporating when moved from an atmosphere into a vacuum. Therefore, it is possible to reduce the generation of the oxide on the surface of the substrate 10 until immediately before processing, even when the next step is performed in a vacuum. A method of applying the liquid material containing the ionic liquid includes, but is not limited to, a spin-coating method and a slit-coating method. Details of the ionic liquid will be described later. The substrate on which the protective film is formed in the atmosphere device is carried out of the atmosphere device into an atmosphere via the loader of the atmosphere device, transferred at the atmosphere by the transfer device, and then carried in the vacuum device via the loader of the vacuum device.

The protective film removal step S14 is performed after the protective film formation step S13, and is a step of removing the protective film formed on the substrate in the vacuum device to expose a clean surface. In the present embodiment, in the protective film removal step S14, as illustrated in FIG. 2D, the substrate 10 is heated in a vacuum to cause a phase transition of the ionic liquid, thereby reducing the adhesiveness of the protective film 14 to the base (the insulating film 11 and the conductive film 12). Then, by physical manipulation of the substrate 10, the protective film 14 on the surface of the substrate 10 is peeled off and removed. The physical manipulation includes, for example, horizontal movement, rotation, and tilt of the substrate 10. The ionic liquid may be phase transferred to reduce the viscosity of the protective film 14.

The vacuum processing step S15 is performed after the protective film removal step S14, and is a step of performing various types of vacuum processing on the substrate in the vacuum device. The various types of vacuum processing include, but are not limited to, deposition processing, etching processing, COR processing, and heat processing. Preferably, the vacuum processing step S15 is performed continuously without exposing the substrate to the atmosphere after the protective film removal step S14 so that impurities do not re-adhere to the clean surface. In the present embodiment, the vacuum processing step S15 is performed continuously after the protective film removal step S14 in the same vacuum device as the device for performing the protective film removal step S14. In the present embodiment, the various types of vacuum processing may be deposition processing for depositing an insulating film 15, for example, as illustrated in FIG. 2E. In the deposition processing, a metal film may be formed in place of the insulating film 15.

As described above, according to the method of manufacturing a semiconductor device according to the first embodiment, the liquid material containing the ionic liquid is preliminarily applied to the surface of the substrate as a protective film, and the protective film is removed in a vacuum immediately before the start of the deposition step. Accordingly, it is possible to reduce the generation of oxide on the surface of the substrate, and a desired film can be formed on a clean surface on which the generation of oxide is reduced. As a result, degradation of the interface properties (for example, electrical properties, mechanical properties) between the surface of the substrate and the desired film can be suppressed.

### (Vacuum Deposition Device)

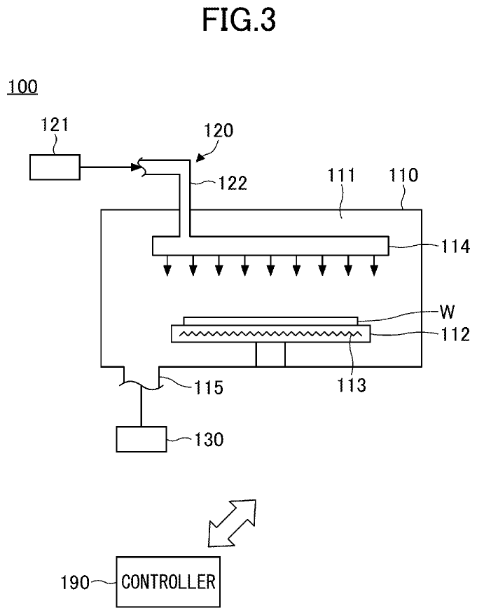

Referring to FIG. 3, an example of a vacuum film deposition device for performing the deposition processing performed in the vacuum processing step S11 and the vacuum processing step S15 will be described. FIG. 3 is a schematic diagram illustrating an example of the vacuum deposition device.

The vacuum deposition device 100 includes a chamber 110, a gas supply 120, an exhaust system 130, and a controller 190.

The chamber 110 forms a processing space 111 of a sealed structure enclosing the wafer W therein. Inside the chamber 110, a mounting platform 112 is mounted.

The mounting platform 112 is generally circular in planar view and is secured to the bottom of the chamber 110. On the mounting platform 112, a wafer W is placed substantially horizontally. In the mounting platform 112, a heater 113 for heating the mounting platform 112 and the wafer W is provided.

The side wall of the chamber 110 is provided with a loading/unloading port (not illustrated) for carrying the wafer W in/out of the processing space 111. The loading/unloading port is opened and closed by a gate valve (not illustrated). The ceiling of the chamber 110 is provided with a showerhead 114 having a plurality of discharge ports for discharging a process gas.

The gas supply 120 includes a gas source 121 and a gas supply path 122. The gas source 121 includes a source of the various types of process gases. The gas supply path 122 connects the gas source 121 to the showerhead 114. In the gas supply path 122, a valve and a flow controller (both not illustrated) are interposed, for example. In the gas supply 120, the various types of process gases from the gas source 121 are discharged to the processing space 111 via the gas supply path 122 and the showerhead 114.

The exhaust system 130 is connected to an exhaust port 115 provided, for example, at the bottom of the chamber 110. The exhaust system 130 includes, for example, a pressure control valve and a vacuum pump (both not illustrated) to evacuate the chamber 110.

The controller 190 processes a computer-executable instruction that causes the vacuum deposition device 100 to execute the vacuum processing step S11 and the vacuum processing step S15. The controller 190 may be configured to control each element of the vacuum deposition device 100 to perform the vacuum processing step S11 and the vacuum processing step S15. The controller 190 includes, for example, a computer. The computer includes, for example, a central processing unit (CPU), a storage unit, and a communication interface.

### (Application Device)

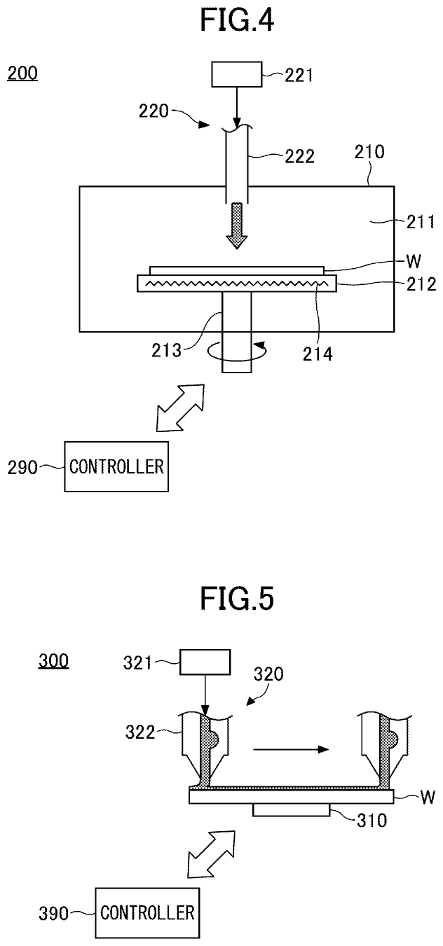

Referring to FIG. 4, a spin coater will be described as an example of an application device for performing the wet processing performed in the atmosphere processing step S12 and applying the liquid material containing the ionic liquid performed in the protective film formation step S13. FIG. 4 is a schematic diagram illustrating an example of the spin coater.

The spin coater 200 includes a housing 210, a liquid supply 220, and a controller 290.

The housing 210 forms a processing space 211 of a sealed structure enclosing the wafer W therein. The housing 210 is provided with a loading/unloading port (not illustrated) for carrying the wafer W in/out of the processing space 211. The loading/unloading port is opened and closed by a gate valve (not illustrated). A mounting platform 212 is provided within the housing 210. The mounting platform 212 is connected to the upper end of a rotating shaft 213 provided through the bottom of the housing 210, and is configured to be rotatable. On the mounting platform 212, the wafer W is placed substantially horizontally. In the mounting platform 212, a heater 214 for heating the wafer W is embedded.

The liquid supply 220 includes a liquid source 221 and a nozzle 222. The liquid source 221 includes a source of a variety of liquid materials such as the chemical liquid containing hydrogen fluoride (HF) and the liquid material containing the ionic liquid. The nozzle 222 is provided through the ceiling of the housing 210 to supply various liquid materials from the liquid source 221 to the surface of the wafer W mounted on the mounting platform 212.

The controller 290 processes a computer-executable instruction that causes the spin coater 200 to perform the wet processing performed in the atmosphere processing step S12 and the application of the liquid material containing the ionic liquid performed in the protective film formation step S13. The controller 290 may be configured to control each element of the spin coater 200 to perform the wet processing performed in the atmosphere processing step S12 and the application of the liquid material containing the ionic liquid performed in the protective film formation step S13. The controller 290 includes, for example, a computer. The computer includes, for example, a CPU, a storage unit, and a communication interface.

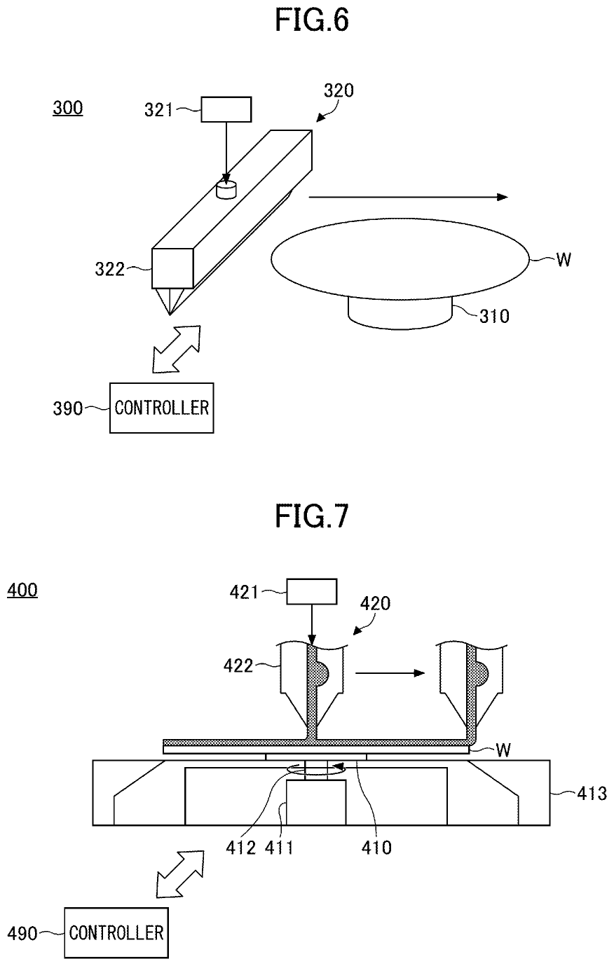

Referring to FIGS. 5 and 6, a slit coater will be described as an example of an application device for performing the wet processing performed in the atmosphere processing step S12 and the application of the liquid material containing the ionic liquid performed in the protective film formation step S13. FIGS. 5 and 6 are schematic diagrams illustrating examples of the slit coater. FIGS. 5 and 6 are a side view and a perspective view, respectively, of the slit coater.

The slit coater 300 includes a stage 310, a liquid supply 320, and a controller 390.

The stage 310 mounts the wafer W in a substantially horizontal state.

The liquid supply 320 includes a liquid supply 321 and a slit nozzle 322. The liquid supply 321 includes a source of a variety of liquid materials such as the chemical solution containing HF and the liquid material containing the ionic liquid. The slit nozzle 322 moves horizontally above the wafer W and supplies the liquid material from the liquid supply 321 to the surface of the wafer W mounted on the stage 310.

The controller 390 processes a computer-executable instruction that causes the slit coater 300 to perform the wet processing performed in the atmosphere processing step S12 and the application of the liquid material containing the ionic liquid performed in the protective film formation step S13. The controller 390 may be configured to control each element of the slit coater 300 to perform the wet processing performed in the atmosphere processing step S12 and the application of the liquid material containing the ionic liquid performed in the protective film formation step S13. The controller 390 includes, for example, a computer. The computer includes, for example, a CPU, a storage unit, and a communication interface.

Referring to FIG. 7, another example of the slit coater will be described as an example of the application device for performing the wet processing performed in the atmosphere processing step S12 and the application of the liquid material containing the ionic liquid performed in the protective film formation step S13. FIG. 7 is a schematic diagram illustrating another example of the slit coater.

The slit coater 400 includes a stage 410, a liquid supply 420, and a controller 490.

The stage 410 mounts the wafer W in a substantially horizontal state. The stage 410 is connected to the upper end of a rotating shaft 412 that is rotated by a drive mechanism 411, and is configured to be rotatable. Around the lower part of the stage 410, a liquid receiver 413 whose upper side is open is provided. The liquid receiver 413 receives the liquid material and the like that drops off or is shaken off the wafer W.

The liquid supply 420 includes a liquid supply 421 and a slit nozzle 422. The liquid supply 421 includes a source of a variety of liquid materials such as the chemical containing HF and the liquid material containing the ionic liquid. The slit nozzle 422 moves horizontally above the wafer W and supplies the liquid material from the liquid supply 421 to the surface of the wafer W mounted on the stage 410.

The controller 490 processes a computer-executable instruction that causes the slit coater 400 to perform the wet processing performed in the atmosphere processing step S12 and the application of the liquid material containing the ionic liquid performed in the protective film formation step S13. The controller 490 may be configured to control each element of the slit coater 400 to perform the wet processing performed in the atmosphere processing step S12 and the application of the liquid material containing the ionic liquid performed in the protective film formation step S13. The controller 490 includes, for example, a computer. The computer includes, for example, a CPU, a storage unit, and a communication interface.

### (Peeling Device)

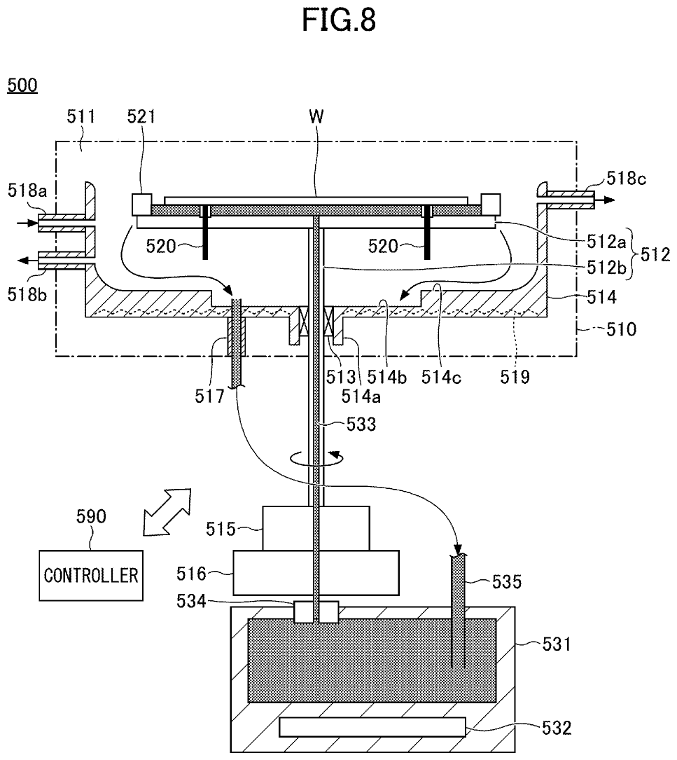

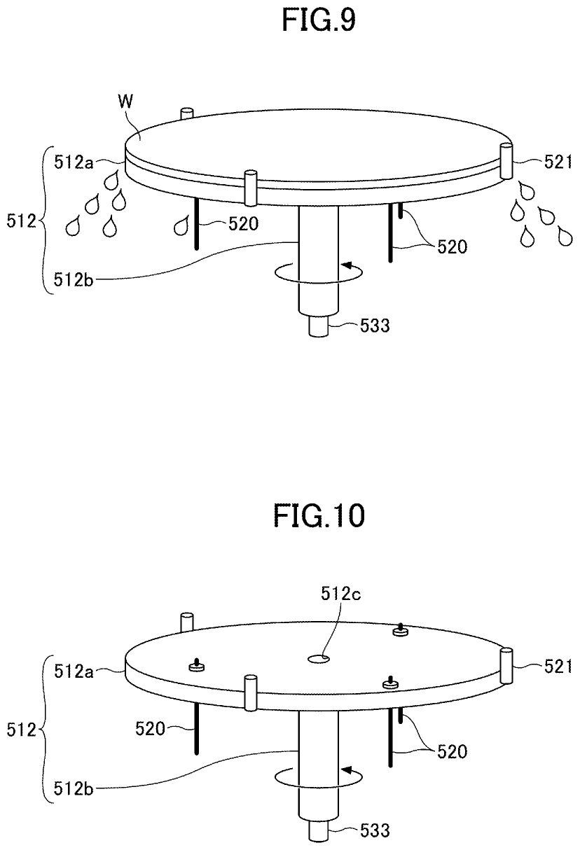

Referring to FIGS. 8 to 10, an example of a peeling device for performing the removal of the protective film performed in the protective film removal step S14 will be described. FIG. 8 is a schematic diagram illustrating an example of the peeling device. FIG. 9 is a diagram illustrating a stage of the peeling device of FIG. 8, illustrating a wafer mounted on the stage, and the space between the stage and the wafer is filled with a temperature control fluid. FIG. 10 is a diagram illustrating the stage of the peeling device of FIG. 8, and illustrates a state in which the wafer is not mounted on the stage and the stage is not filled with the temperature control fluid.

The peeling device 500 includes a chamber 510, a liquid circulator 530, an exhaust system 540, and a controller 590.

The chamber 510 forms a processing space 511 of a sealed structure enclosing the wafer W therein. Inside the chamber 510, a stage 512 is provided.

The stage 512 holds the wafer W in a substantially horizontal state. The stage 512 includes a retainer 512a and a rotating shaft 512b. The rotating shaft 512b is rotatably and liftably supported, for example, via a spline seal bearing 513, to an annular support 514a at the bottom of the reactor 514. The stage 512 is coupled to a rotating drive shaft of the motor 515. The stage 512 is supported liftably by a lifting mechanism 516. Control signals of the motor 515 and the lifting mechanism 516 are output from the controller 590. The stage 512 is surrounded by a cylindrical reactor 514 with a bottom.

The reactor 514 has a central bottom 514b and a peripheral bottom 514c, for example, which are concentrically different in depth, and the central bottom 514b is deeper than the peripheral bottom 514c. The liquid in the reactor 514 flows smoothly from the peripheral bottom 514c toward the central bottom 514b. The two-stage step structure may not be used as long as the liquid flows smoothly. For example, a conical shape or a multi-stage structure in which the center portion is deep may be used.

A drain 517 opens to the central bottom 514b. A return tube 535 of the liquid circulator 530 is connected to the drain 517. A liquid supply flow path 518a opens to the side of the reactor 514. A drain flow path 518b is opened at a position on the side of the reactor 514 lower than the liquid supply flow path 518a. A plurality of exhaust paths 518c communicate with a side portion of the reactor 514 at a position higher than the liquid supply flow path 518a. At the bottom of the reactor 514, a heater 519 for heating the temperature control fluid supplied into the wafer W and the reactor 514 is embedded.

Three lift pins 520 are provided above the bottom of the reactor 514. The lift pin 520 lifts and holds the wafer W when the stage 512 is lowered, by penetrating through holes in the stage 512 and projecting against the upper surface of the stage 512.

In the outer edge of the stage 512, a stopper 521 for fixing the wafer W held in the stage 512 is provided. Three stoppers 521, for example, are provided on the outer edge of the stage 512 at equal intervals in the circumferential direction, as illustrated in FIGS. 9 and 10. By fixing the wafer W by the stopper 521, it is possible to prevent the wafer W from being detached from the stage 512 when the wafer W is rotated.

The liquid circulator 530 includes a tank 531, a temperature control mechanism 532, a forward tube 533, a sealing mechanism 534, and a return tube 535.

The tank 531 stores the temperature control fluid. The temperature control fluid is supplied between the upper surface of the stage 512 and the lower surface of the wafer W from inside the tank 531 through the forward tube 533. As a result, the temperature of the wafer W is adjusted to approximately the same temperature as the temperature of the temperature control fluid. As the temperature controlling fluid, it is preferable to use the ionic liquid in view of excellent thermal conductivity. As the ionic liquid, the same ionic liquid as the ionic liquid constituting the protective film formed on the surface of the wafer W can be used.

The temperature control mechanism 532 includes a heater and a temperature sensor (both not illustrated). The temperature control mechanism 532 controls the heater based on the detected value of the temperature sensor to control the temperature of the temperature control fluid in the tank 531.

The forward tube 533 is co-axially disposed with the rotating shaft 512b of the stage 512 and rotates and moves up and down with the rotating shaft 512b by the motor 515 and the lifting mechanism 516. The forward tube 533 is passed through an opening 512c having a top end at the center of the stage 512, and supplies the temperature control fluid to the stage 512, as illustrated in FIG. 10.

The sealing mechanism 534 rotatably supports the forward tube 533 in an airtightly sealed state.

The return tube 535 is connected to the drain 517 and collects the temperature control fluid spilled from the stage 512 into the tank 531.

The exhaust system 540 is connected, for example, to a plurality of exhaust paths 518c. The exhaust system 540 includes, for example, a pressure control valve and a vacuum pump (both not illustrated) to evacuate the chamber 510.

The controller 590 processes a computer-executable instruction that causes the peeling device 500 to execute the protective film removal step S14. The controller 590 may be configured to control each element of the peeling device 500 to perform the protective film removal step S14. The controller 590 includes, for example, a computer. The computer includes, for example, a CPU, a storage unit, and a communication interface.

### Second Embodiment

### (Method of Manufacturing Semiconductor Device)

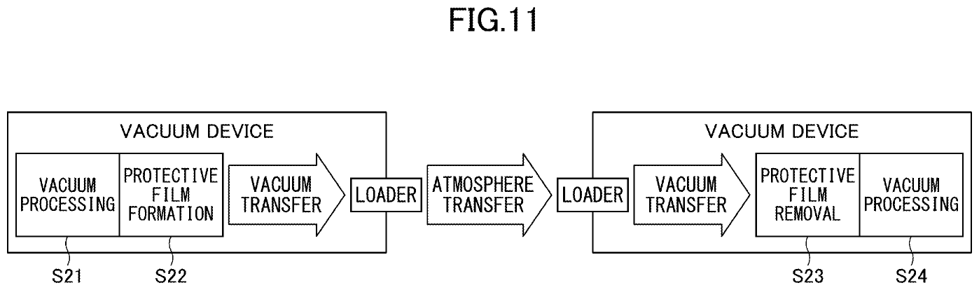

Referring to FIG. 11, an example of a method of manufacturing a semiconductor device according to a second embodiment will be described. FIG. 11 is a diagram illustrating an example of the method of manufacturing a semiconductor device according to the second embodiment.

The method of manufacturing a semiconductor device according to the second embodiment includes a vacuum processing step S21, a protective film formation step S22, a protective film removal step S23, and a vacuum processing step S24. The vacuum processing step S21, the protective film formation step S22, the protective film removal step S23, and the vacuum processing step S24 are performed in a vacuum.

The vacuum processing step S21 is a step of performing various types of vacuum processing on a substrate in a vacuum device. The vacuum processing step S21 may be the same as, for example, the vacuum processing step S11 of the first embodiment.

The protective film formation step S22 is performed after the vacuum processing step S21, and is a step of applying a liquid material containing an ionic liquid to the substrate in the vacuum device to form a protective film on the surface of the substrate. The protective film formation step S22 is performed in order to protect the surface of the substrate from contamination of the clean surface with impurities such as oxygen (O), water (H₂O), organic matter, and the like, and to prevent the formation of the natural oxide film. Therefore, it is preferable that the protective film formation step S22 is performed continuously after the vacuum processing step S21. According to the present embodiment, the protective film formation step S22 is continuously performed after the vacuum processing step S21 in the same vacuum device as the device for performing the vacuum processing step S21. The protective film formed of the liquid material containing the ionic liquid has a property of not evaporating easily in a vacuum, and thus the application can be performed in a vacuum. In addition, it is possible to reduce the generation of the oxide on the surface of the substrate until immediately before processing, even when the next step is performed in a vacuum. A method of applying the liquid material containing the ionic liquid includes, but is not limited to, a spin-coating method and a slit-coating method. The substrate on which the protective film is formed in the vacuum device is carried out of the vacuum device into an atmosphere via the loader of the vacuum device, transferred at the atmosphere by the transfer device, and then carried in another vacuum device via the loader of the another vacuum device.

The protective film removal step S23 is performed after the protective film formation step S22, and is a step of exposing a clean surface by removing the protective film formed on the substrate in the vacuum device. The protective film removal step S23 may be the same as, for example, the protective film removal step S14 of the first embodiment.

The vacuum processing step S24 is performed after the protective film removal step S23, and is a step of performing various types of vacuum processing to the substrate in the vacuum device. The vacuum processing step S24 may be the same as, for example, the vacuum processing step S15 of the first embodiment.

As described above, according to the method of manufacturing a semiconductor device according to the second embodiment, the liquid material containing the ionic liquid is previously applied to the surface of the substrate as a protective film, and the protective film is removed in a vacuum immediately before the start of the deposition step. Accordingly, it is possible to reduce the generation of oxide on the surface of the substrate, and a desired film can be formed on a clean surface on which the generation of oxide is reduced. As a result, degradation of the interface properties (for example, electrical properties, mechanical properties) between the surface of the substrate and the desired film can be suppressed.

### (Vacuum Application Device)

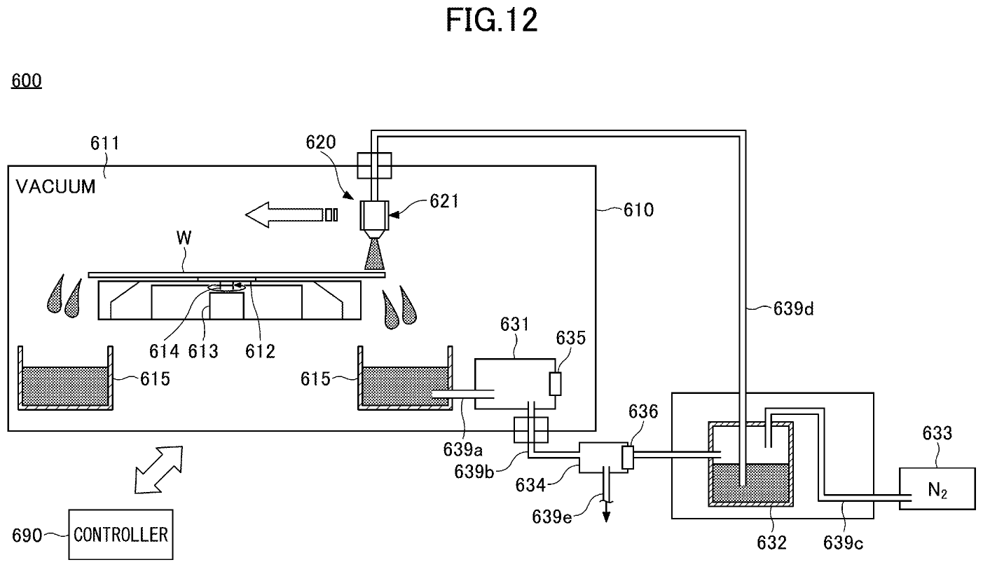

Referring to FIG. 12, a vacuum slit coater as an example of a vacuum application device for performing the application of the liquid material containing the ionic liquid performed in the protective film formation step S22 will be described. FIG. 12 is a schematic diagram illustrating an example of the vacuum slit coater.

A vacuum slit coater 600 includes a chamber 610, a liquid supply 620, a liquid circulator 630, and a controller 690.

The chamber 610 forms a processing space 611 of a sealed structure enclosing the wafer W therein. Inside the chamber 610, a stage 612 is provided. The stage 612 holds the wafer W in a substantially horizontal state. The stage 612 is connected to the upper end of a rotating shaft 614 that is rotated by a drive mechanism 613, and is configured to be rotatable. Around the lower part of the stage 612, a liquid receiver 615 whose upper side is open is provided with. The liquid receiver 615 receives and stores the chemical solution, the liquid material, and the like that drops off or is shaken off the wafer W. The interior of the chamber 610 is evacuated by an evacuation system (not illustrated) including a pressure control valve, a vacuum pump, and the like.

The liquid supply 620 includes a slit nozzle 621. The slit nozzle 621 moves horizontally above the wafer W and supplies the liquid material containing the ionic liquid from the liquid circulator 630 to the surface of the wafer W mounted on the stage 612.

The liquid circulator 630 collects the liquid material containing the ionic liquid stored in the liquid receiver 615 and supplies the liquid material to the slit nozzle 621. The liquid circulator 630 includes a compressor 631, a stock tank 632, a carrier gas source 633, a cleaner 634, and pH sensors 635 and 636.

The compressor 631 is connected to the liquid receiver 615 via a pipe 639a, and collects the liquid material containing the ionic liquid stored in the liquid receiver 615 and compresses it to, for example, atmospheric pressure or higher. The compressor 631 is connected to the stock tank 632 via a pipe 639b, and transports a compressed liquid material containing the ionic liquid to the stock tank 632 via the pipe 639b. In the pipe 639a, a valve and a flow controller (both not illustrated) are interposed, for example. For example, by controlling opening and closing of the valve, the liquid material containing the ionic liquid is periodically transported from the compressor 631 to the stock tank 632.

The stock tank 632 stores the liquid material containing the ionic liquid. The pipes 639b to 639d are inserted at one end into the stock tank 632. The other end of the pipe 639b is connected to the compressor 631, and the liquid material containing the ionic liquid that is compressed by the compressor 631 is supplied to the stock tank 632 via the pipe 639b. The other end of the pipe 639c is connected to the carrier gas source 633, and a carrier gas such as nitrogen (N₂) gas and the like is supplied to the stock tank 632 from the carrier gas source 633 via the pipe 639c. The other end of the pipe 639d is connected to the slit nozzle 621, and the liquid material containing the ionic liquid in the stock tank 632 together with the carrier gas is transported via the pipe 639d to the slit nozzle 621. In the pipes 639b to 639d, valves and flow controllers (both not illustrated) are interposed, for example.

The carrier gas source 633 is connected to the stock tank 632 via the pipe 639c, and supplies a carrier gas such as N₂ gas and the like to the stock tank 632 via the pipe 639c. The cleaner 634 is interposed in the pipe 639b. The cleaner 634 cleans the liquid material containing the ionic liquid transported from the compressor 631. A drain 639e is connected to the cleaner 634, and the liquid material containing the ionic liquid whose properties have deteriorated is discharged through the drain 639e. For example, the cleaner 634 controls whether to reuse or drain the liquid material containing the ionic liquid based on the detected value of the pH sensor 636. The cleaner 634 may also, for example, control whether to reuse or drain the liquid material containing the ionic liquid based on the detected value of the pH sensor 635. For example, the cleaner 634 may control whether to reuse or drain the liquid material containing the ionic liquid based on the detected values of the pH sensor 635 and the pH sensor 636.

The pH sensor 635 is provided in the compressor 631, and detects the hydrogen ion index (pH) of the liquid material containing the ionic liquid in the compressor 631.

The pH sensor 636 is provided in the cleaner 634, and detects the hydrogen ion index (pH) of the liquid material containing the ionic liquid in the cleaner 634.

The controller 690 processes a computer-executable instruction that causes the vacuum slit coater 600 to perform the application of the liquid material containing the ionic liquid in the protective film formation step S22. The controller 690 may be configured to control each element of the vacuum slit coater 600 to perform the application of the liquid material containing the ionic liquid in the protective film formation step S22. The controller 690 includes, for example, a computer. The computer includes, for example, a CPU, a storage unit, and a communication interface.

### Third Embodiment

### (Method of Manufacturing Semiconductor Device)

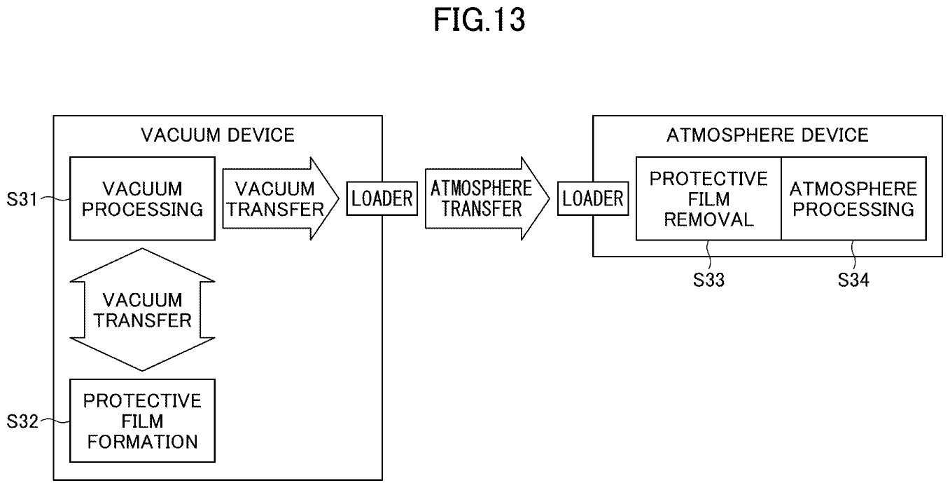

Referring to FIG. 13, an example of a method of manufacturing a semiconductor device according to a third embodiment will be described. FIG. 13 is a diagram illustrating an example of the method of manufacturing a semiconductor device according to the third embodiment.

The method of manufacturing a semiconductor device according to the third embodiment includes a vacuum processing step S31, a protective film formation step S32, a protective film removal step S33, and an atmosphere processing step S34. The vacuum processing step S31 and the protective film formation step S32 are performed in a vacuum, and the protective film removal step S33 and the atmosphere processing step S34 are performed at the atmosphere.

The vacuum processing step S31 is a step of performing various types of vacuum processing on a substrate in a vacuum device. The vacuum processing step S31 may be the same as, for example, the vacuum processing step S11 of the first embodiment.

The protective film formation step S32 is performed after the vacuum processing step S31, and is a step of applying a liquid material containing an ionic liquid to the substrate in the vacuum device to form a protective film on the surface of the substrate. In the present embodiment, the protective film formation step S32 is performed in a different process module connected via a vacuum transfer chamber to the process module in which the vacuum processing step S31 is performed. The substrate on which the protective film is formed in the vacuum device is carried out of the vacuum device into the atmosphere by the loader of the vacuum device, transferred at the atmosphere by the transfer device, and then carried in the atmosphere device via the loader of the atmosphere device.

The protective film removal step S33 is performed after the protective film formation step S32, and is a step of exposing a clean surface by removing the protective film formed on the substrate in the atmosphere device. In the present embodiment, in the protective film removal step S33, the substrate is heated at the atmosphere to cause a phase transition of the ionic liquid, thereby reducing the adhesiveness of the protective film to the substrate (the insulating material and the conductive material). Then, by physical manipulation of the substrate, the protective film on the surface of the substrate is then peeled off and removed. The physical manipulation includes, for example, horizontal movement, rotation, and tilt of the substrate. The ionic liquid may be phase transferred to reduce the viscosity of the protective film.

The atmosphere processing step S34 is performed after the protective film removal step S33, and is a step of performing various types of atmosphere processing on the substrate in the atmosphere device. The various types of atmosphere processing include, but are not limited to, wet processing, atmospheric pressure deposition processing, and plating. The atmosphere processing step S34 is preferably performed simultaneously with the protective film removal step S33 or continuously after the protective film removal step S33 so that impurities do not re-adhere to the clean surface.

As described above, according to the method of manufacturing a semiconductor device according to the third embodiment, the liquid material containing the ionic liquid is previously applied to the surface of the substrate as a protective film, and the protective film is removed in a vacuum immediately before the start of the deposition step. Accordingly, it is possible to reduce the generation of oxide on the surface of the substrate, and a desired film can be formed on a clean surface on which the generation of oxide is reduced. As a result, degradation of the interface properties (for example, electrical properties, mechanical properties) between the surface of the substrate and the desired film can be suppressed.

### Fourth Embodiment

### (Method of Manufacturing Semiconductor Device)

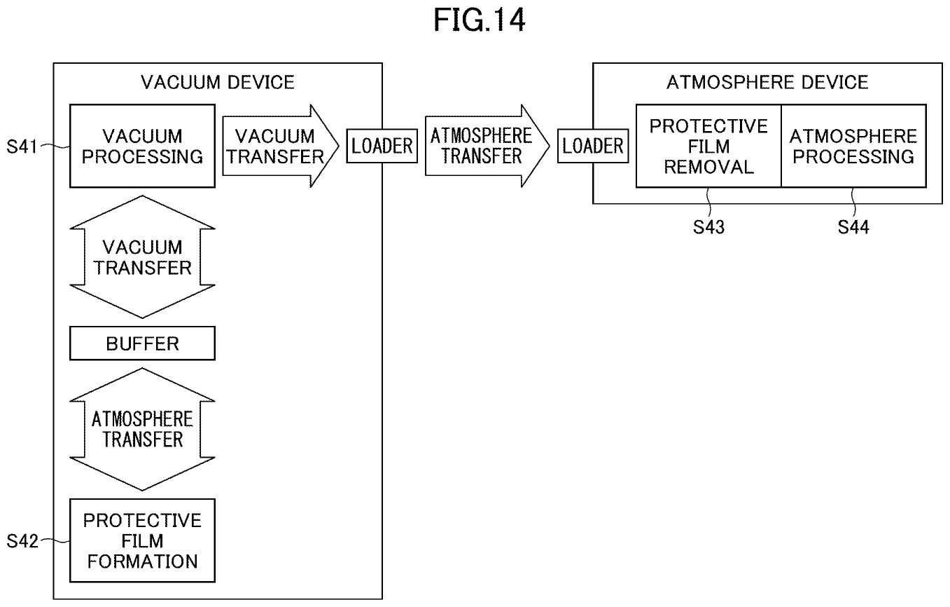

Referring to FIG. 14, an example of a method of manufacturing a semiconductor device according to a fourth embodiment will be described. FIG. 14 is a diagram illustrating an example of the method of manufacturing a semiconductor device according to the fourth embodiment.

The method of manufacturing a semiconductor device according to the fourth embodiment includes a vacuum processing step S41, a protective film formation step S42, a protective film removal step S43, and an atmosphere processing step S44. The vacuum processing step S41 and the protective film formation step S42 are performed in a vacuum, and the protective film removal step S43 and the atmosphere processing step S44 are performed at the atmosphere.

The vacuum processing step S41 is a step of performing various types of vacuum processing on a substrate in a vacuum device. The vacuum processing step S41 may be the same as, for example, the vacuum processing step S11 of the first embodiment.

The protective film formation step S42 is performed after the vacuum processing step S41, and is a step of applying a liquid material containing an ionic liquid to the substrate in the vacuum device to form a protective film on the surface of the substrate. In the present embodiment, the protective film formation step S42 is performed in a different process module connected via a load-lock chamber (buffer) to the process module in which the vacuum processing step S41 is performed. The load-lock chamber is configured such that the interior can be switched between a vacuum atmosphere and an atmospheric atmosphere. The substrate on which the protective film is formed in the vacuum device is carried out of the vacuum device into the atmosphere via the loader of the vacuum device, transferred at the atmosphere by the transfer device, and then carried in the atmosphere device via the loader of the atmosphere device.

The protective film removal step S43 is performed after the protective film formation step S42, and is a step of exposing a clean surface by removing the protective film formed on the substrate in the atmosphere device. The protective film removal step S43 may be the same as the protective film removal step S33 of the third embodiment.

The atmosphere processing step S44 is performed after the protective film removal step S43, and is a step of performing various types of atmosphere processing to the substrate in the atmosphere device. The atmosphere processing step S44 may be the same as atmosphere processing step S34 of the third embodiment.

As described above, according to the method of manufacturing a semiconductor device according to the fourth embodiment, the liquid material containing the ionic liquid is previously applied to the surface of the substrate as a protective film, and the protective film is removed in a vacuum immediately before the start of the deposition step. Accordingly, it is possible to reduce the generation of oxide on the surface of the substrate, and a desired film can be formed on a clean surface on which the generation of oxide is reduced. As a result, degradation of the interface properties (for example, electrical properties, mechanical properties) between the surface of the substrate and the desired film can be suppressed.

### Ionic Liquid

The ionic liquid is an ionic compound that is liquid at room temperature, and is composed of cations and anions. The ionic liquid used in the embodiments is an ionic liquid whose physical properties change depending on environmental factors. The environmental factors include, for example, temperature. The physical properties include, for example, at least one of viscosity and adhesiveness.

As an example of the ionic liquid used in the embodiments, an ionic liquid that undergoes a reversible phase transition depending on temperature can be preferably used. Accordingly, by changing the temperature of the substrate, a phase transition occurs in the ionic liquid, and the adhesiveness between the ionic liquid and the substrate can be changed. That is, by controlling the temperature of the ionic liquid, it is possible to change the ionic liquid to a state in which the ionic liquid adheres to the substrate (wafer) as a viscous film, or to a non-viscous state in which the ionic liquid is easily peeled off from the substrate (wafer).

For example, when the liquid material containing the ionic liquid is applied on the substrate to form a protective film, the temperature of the substrate is set to a first temperature so that the adhesiveness between the ionic liquid and the substrate is increased. As a result, the liquid material applied on the substrate remains on the substrate to form a protective film. In contrast, when removing the protective film formed on the substrate, the temperature of the substrate is set to a second temperature different from the first temperature so that the adhesiveness between the ionic liquid and the substrate is reduced. As a result, the protective film whose adhesiveness to the substrate has deteriorated can be easily peeled off from the substrate when, for example, a physical operation such as horizontal movement, rotation, or tilt of the substrate is performed.

Examples of the cations constituting the ionic liquid include cations of the pyridinium type, the imidazolium type, the ammonium type, the pyrrolidinium type, and the piperidinium type, which contain quaternary nitrogen, and cations of the phosphonium type, containing quaternary phosphorus. These cations include an alkyl group —(CH₂)ₙCH₃ as a side chain.

The pyridinium-type cations include, but are not limited to, C₂py⁺ as represented by the chemical formula (C1-1), and C₄py⁺ as represented by the chemical formula (C1-2).

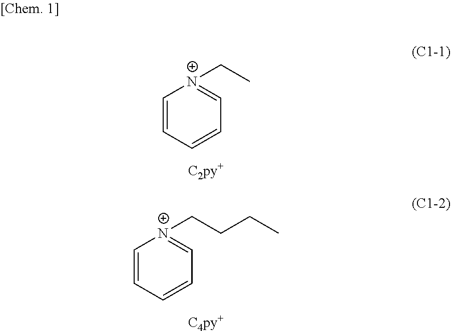

The imidazolium-type cations include, but are not limited to, C₂mim⁺ as represented by the chemical formula (C2-1), C₄mim⁺ as represented by the chemical formula (C2-2), C₆mim⁺ as represented by the chemical formula (C2-3), and C₈mim⁺ as represented by the chemical formula (C2-4).

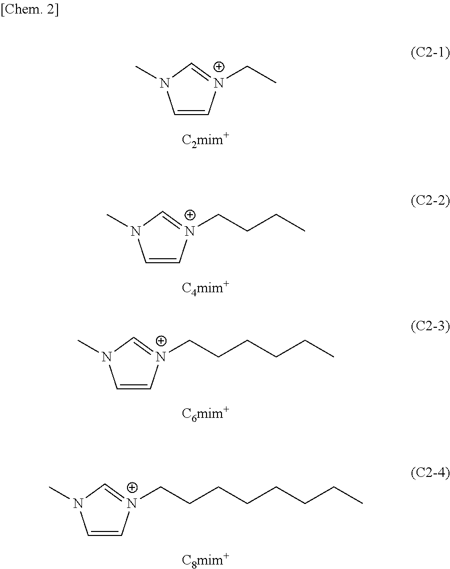

The ammonium-type cations include, but are not limited to, N_{3, 1, 1, 1}⁺ as represented by the chemical formula (C3-1), N_{4, 1, 1, 1}⁺ as represented by the chemical formula (C3-2), N_{6, 1, 1, 1}⁺ as represented by the chemical formula (C3-3), N_{2, 2, 1, (201)}⁺ as represented by the chemical formula (C3-4), and Ch⁺ as represented by the chemical formula (C3-5).

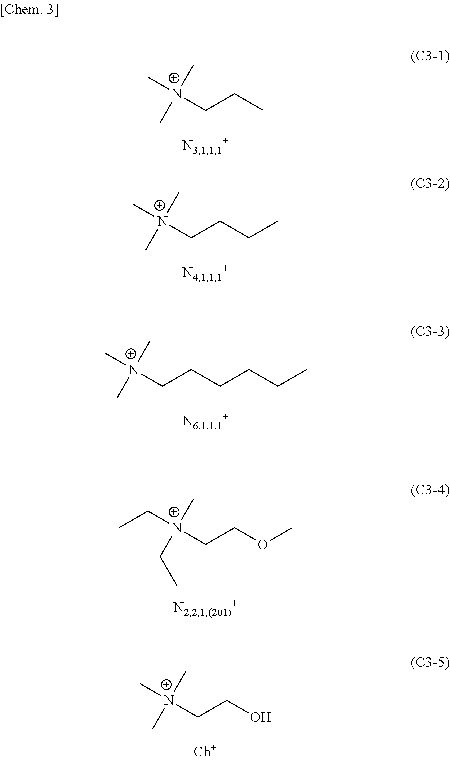

The pyrrolidinium-type cations include, but are not limited to, Pyr_{1,3}⁺ as represented by the chemical formula (C4-1), and Pyr_{1,4}⁺ as represented by the chemical formula (C4-2).

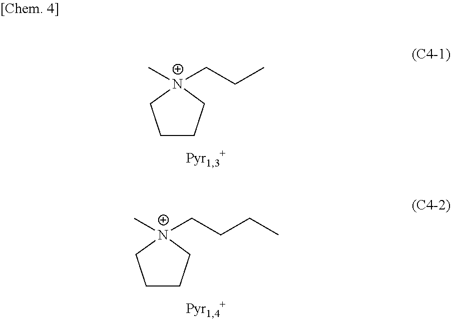

The piperidinium-type cations include, but are not limited to, Pip_{1,3}⁺ as represented by the chemical formula (C5-1), and Pip_{1,4}⁺ as represented by the chemical formula (C5-2).

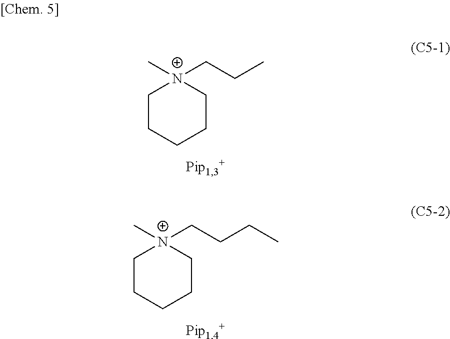

The phosphonium-type cations include, but are not limited to, P_{5, 2, 2, 2}⁺ as represented by the chemical formula (C6-1), and P_{6, 6, 6, 14}⁺ as represented by the chemical formula (C6-2).

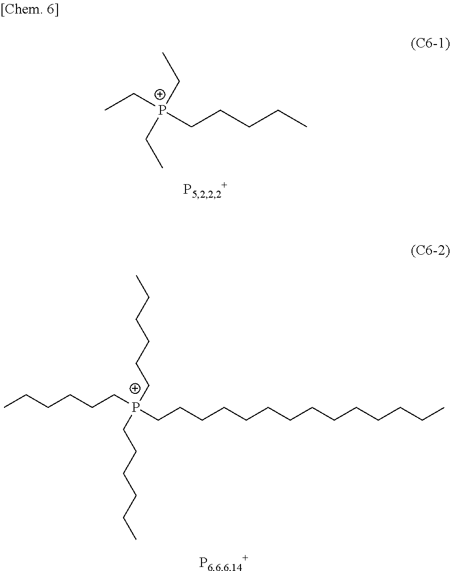

The anions that constitute the ionic liquid include, but are not limited to, TfO⁻ as represented by the chemical formula (A1), Tf₂N⁻ (TFSA⁻) as represented by the chemical formula (A2), Tf₃C⁻ as represented by the chemical formula (A3), FSA⁻ as represented by the chemical formula (A4), CH₃COO⁻ as represented by the chemical formula (A5), CF₃COO⁻ as represented by the chemical formula (A6), BF₄⁻ as represented by the chemical formula (A7), PF₆⁻ as represented by the chemical formula (A8), (CN)₂N⁻ as represented by the chemical formula (A9), AlCl₄⁻ as represented by the chemical formula (A10), and Al₂Cl₇⁻ as represented by the chemical formula (A11).

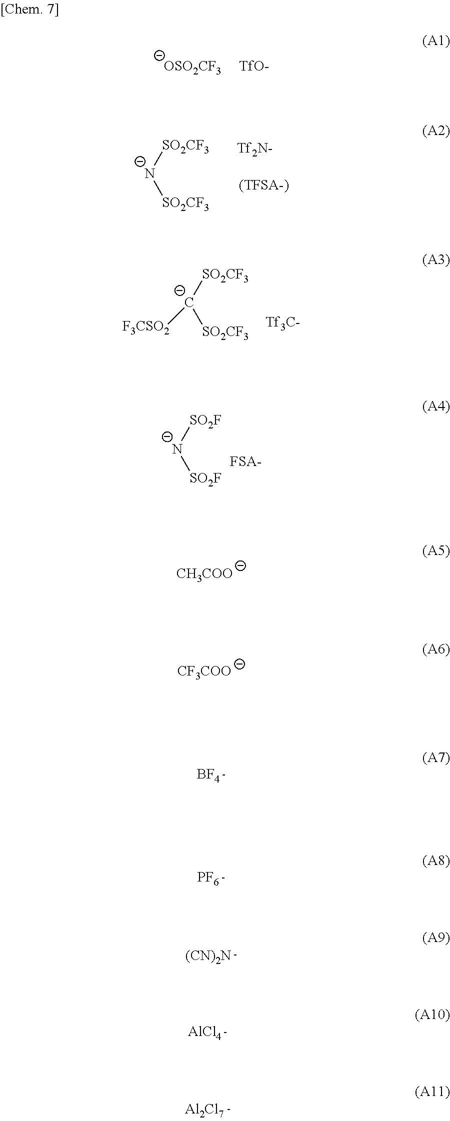

Specific examples of the ionic liquid include tributylhexadecylphosphonium 3-(trimethylsilyl)-1-propanesulfonate (BHDP·DSS), and N,N-diethyl-N-methyl-N (2-methoxyethyl) ammonium tetrafluoroborate (DEME·BF₄).

### EXAMPLE

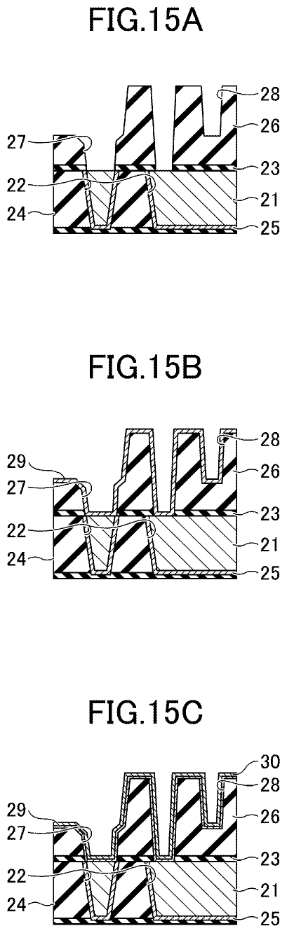

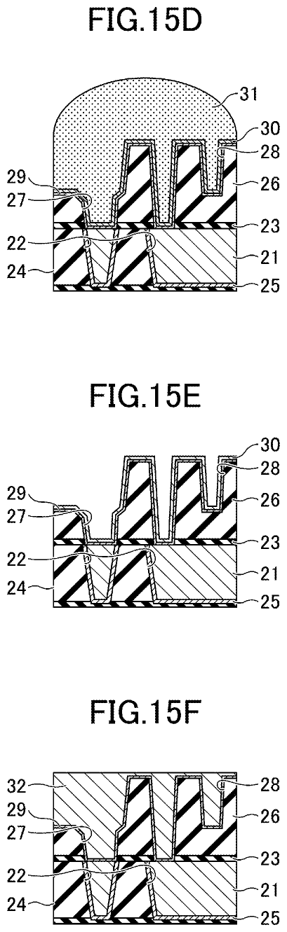

Referring to FIGS. 15A to 15F, as an application example of a method of manufacturing a semiconductor device of the embodiments, a case where Cu is embedded in a via in a back end of line (BEOL) process is illustrated. FIGS. 15A to 15F are process cross-sectional diagrams illustrating examples of a method of embedding Cu in a via formed in a laminated film.

First, as illustrated in FIG. 15A, a substrate 20 on which an insulating film 26 is formed on the lower wiring 21 is prepared. An etch stop layer 23 is formed between the lower wiring 21 and the insulating film 26. The lower wiring 21 is embedded in a trench 22 formed in an interlayer insulating film 24 with a barrier metal film 25 interposed therebetween. The lower wiring 21 includes, but is not limited to, Cu wiring. Examples of the etch stop layer 23 include, but are not limited to, a silicon carbonitride film (SiCN film). Examples of the interlayer insulating film 24 include, but are not limited to, low-k film. Examples of the barrier metal film 25 include, but are not limited to, tantalum nitride (TaN) film. A via 27 and a trench 28 are formed in the insulating film 26.

Subsequently, as illustrated in FIG. 15B, a TaN film 29 is conformally deposited as a barrier metal film inside the via 27 and the trench 28. Examples of the deposition method of the TaN film 29 include, but are not limited to, an ALD method performed in a vacuum device.

Then, as illustrated in FIG. 15C, the Cu seed film 30 is conformally deposited as a seed film on the TaN film 29. A method of forming the Cu seed film 30 includes, but are not limited to, a PVD method, for example. The Cu seed film is deposited, for example, in a different module in the same device as the vacuum device for depositing the TaN film 29.

Subsequently, as illustrated in FIG. 15D, the liquid material containing the ionic liquid is applied to the substrate 20 to form a protective film 31 to cover the surface of the Cu seed film 30. The protective film 31 is deposited, for example, in a different module in the same device as the vacuum device for depositing the TaN film 29 and the Cu seed film 30. The ionic liquid include, but are not limited to, an ionic liquid that undergoes a reversible phase transition depending on temperature, for example.

Subsequently, as illustrated in FIG. 15E, by physical manipulation such as horizontal movement, rotation, and tilt of the substrate 20 while reducing the adhesiveness between the Cu seed film 30 and the protective film 31, the protective film 31 on the surface of the Cu seed film 30 is peeled off and removed. A method of removing the protective film 31 includes, for example, a method using a spin coater performed in the atmosphere device. For example, the protective film 31 may be removed by rotating the substrate 20 by the spin coater while reducing the adhesiveness between the protective film 31 and the Cu seed film 30 by heating the substrate 20.

Subsequently, as illustrated in FIG. 15F, a Cu 32 is embedded within the via 27 and the trench 28. The step of embedding the Cu 32 is performed, for example, in the same device as the atmosphere device that removes the protective film 31. At this time, by removing the protective film 31 covering the surface of the Cu seed film 30 immediately before embedding the Cu 32, the Cu 32 can be embedded on the Cu seed film 30 having reduced oxidation of the surface. This prevents the decrease in the adhesiveness between the Cu seed film 30 and the Cu 32 and improves the resistance to stress migration (SM) and electro migration (EM). In contrast, when the protective film 31 is not used, because the surface of the Cu seed film 30 is easily oxidized before the Cu 32 is embedded, the adhesiveness between the Cu seed film 30 and the Cu 32 is reduced, and thus SM failure and EM failure are likely to occur. A method of embedding the Cu 32 includes, but is not limited to, a plating method. Examples of the plating method include electroless deposition (ELD) and electrochemical deposition (ECD). The embedding of the Cu 32 into the interior of the via 27 and trench 28 is performed in the same module (spin coater) in the same device as the atmosphere device used to remove the protective film 31, for example.

As described above, according to the example, after the Cu seed film 30 is deposited, the liquid material containing the ionic liquid is applied to the surface of the Cu seed film 30 to form the protective film 31, and the protective film 31 is removed immediately before embedding the Cu 32. Therefore, it is possible to reduce the generation of the natural oxide film on the surface of the Cu seed film 30.

It should be noted that although the example described above describes the case where the TaN film 29 and the Cu seed film 30 are formed inside the via 27 and the trench 28, then the protective film 31 is formed, then the protective film 31 is removed, and then the Cu 32 is embedded, the present disclosure is not limited thereto. For example, the Cu seed film 30 may be omitted.

### [Modification of Slit Coater]

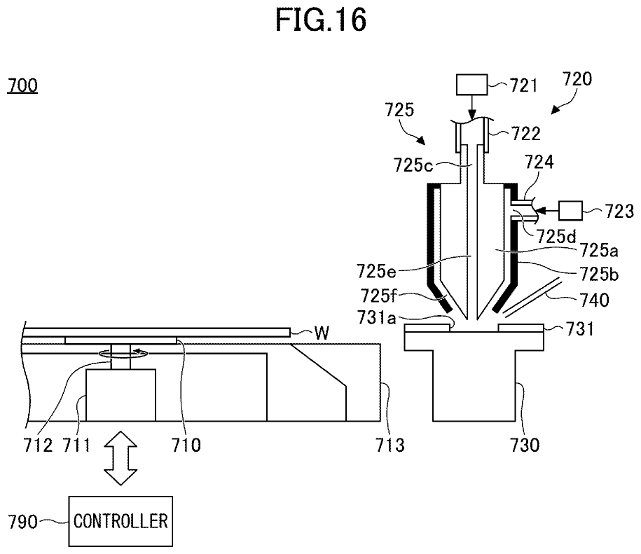

Referring to FIG. 16, a configuration of a slit coater according to the first modification will be described. FIG. 16 is a schematic diagram illustrating the slit coater according to the first modification.

A slit coater 700 includes a stage 710, a liquid supply 720, a sub-stage 730, a concentration measurement nozzle 740, and a controller 790.

The stage 710 mounts the wafer W in a substantially horizontal state. The stage 710 is connected to the upper end of a rotating shaft 712 which is rotated by a drive mechanism 711, and is configured to be rotatable. Around the lower part of the stage 710, a liquid receiver 713 whose upper side is open is provided. The liquid receiver 713 receives the liquid material and the like that drops off or is shaken off the wafer W.

The liquid supply 720 includes an ionic liquid supply 721, an ionic liquid supply pipe 722, a cleaning liquid supply 723, a cleaning liquid supply pipe 724, and a slit nozzle 725.

The ionic liquid supply 721 supplies an ionic liquid IL to the slit nozzle 725 via the ionic liquid supply pipe 722. The ionic liquid IL may be the ionic liquid as described above.

The ionic liquid supply pipe 722 is a pipe that supplies the ionic liquid IL from the ionic liquid supply 721 to the slit nozzle 725. The ionic liquid supply pipe 722 is formed of, for example, a conductive member.

The cleaning liquid supply 723 supplies a cleaning liquid CL to the slit nozzle 725 via the cleaning liquid supply pipe 724. The cleaning liquid CL is preferably a liquid material commonly used in a semiconductor cleaning step including isopropyl alcohol (IPA), but may be a cleaning agent used in other semiconductor steps (for example, an acidic cleaning agent such as phosphoric acid, hydrofluoric acid, hydrochloric acid, nitric acid, and the like, or an alkaline cleaning agent such as SC1 (NH₄OH/H₂O₂/H₂O)).

The cleaning liquid supply pipe 724 is a pipe for supplying the cleaning liquid CL from the cleaning liquid supply 723 to the slit nozzle 725. The cleaning liquid supply pipe 724 is formed of, for example, a conductive member.

The slit nozzle 725 moves horizontally above the wafer W and supplies the ionic liquid IL and the cleaning liquid CL to the surface of the wafer W mounted on the stage 710. The slit nozzle 725 moves above the sub-stage 730 and supplies the ionic liquid IL and the cleaning liquid CL to the sub-stage 730. The slit nozzle 725 includes a body 725a, an outer skin 725b, an ionic liquid supply port 725c, and a cleaning liquid supply port 725d.

The body 725a has an ionic liquid flow path 725e therein. The ionic liquid flow path 725e is connected to the ionic liquid supply pipe 722 via an ionic liquid supply port 725c formed on the top of the body 725a. Thus, the ionic liquid IL from the ionic liquid supply 721 is supplied to the ionic liquid flow path 725e via the ionic liquid supply pipe 722 and the ionic liquid supply port 725c and discharged from the lower end of the ionic liquid flow path 725e. The body 725a is formed, for example, of an insulating member. The cross-sectional area of the ionic liquid flow path 725e is optimized according to the viscosity and contact angle (wettability) of the ionic liquid IL.

The outer skin 725b is provided outside the body 725a so as to form a cleaning liquid flow path 725f between the outer surface of the body 725a and the outer surface thereof. The cleaning liquid flow path 725f is connected to the cleaning liquid supply pipe 724 through the cleaning liquid supply port 725d. Therefore, the cleaning liquid CL from the cleaning liquid supply 723 is supplied to the cleaning liquid flow path 725f via the cleaning liquid supply pipe 724 and the cleaning liquid supply port 725d, and discharged from the lower end of the cleaning liquid flow path 725f. The outer skin 725b is formed, for example, of an electrically conductive member. The cross-sectional area of the cleaning liquid flow path 725f is optimized according to the viscosity and contact angle (wettability) of the cleaning liquid CL.

Thus, the slit nozzle 725 has a double pipe structure including the ionic liquid flow path 725e and the cleaning liquid flow path 725f formed by the body 725a and the outer skin 725b. This allows the ionic liquid IL and the cleaning liquid CL to be applied by one slit nozzle 725.

The sub-stage 730 is provided in a position where the liquid supply 720 can apply the ionic liquid IL and the cleaning liquid CL, apart from the stage 710. In the example of FIG. 16, the sub-stage 730 is provided to the side of the stage 710. On the upper surface of the sub-stage 730, a plate member 731 having an opening 731a in the region where the ionic liquid IL and the cleaning liquid CL are applied, is provided. The sub-stage 730 is configured so that the temperature of the upper surface can be adjusted by heating means or cooling means. The heating means may be, for example, a heater embedded within the sub-stage 730. The cooling means may be, for example, a refrigerant flow path formed within the sub-stage 730.

The concentration measurement nozzle 740 is formed of, for example, a tubular member. The concentration measurement nozzle 740 is provided at a position where one end contacts the ionic liquid IL and the cleaning liquid CL applied on the sub-stage 730. Thus, when the ionic liquid IL and the cleaning liquid CL are applied to the sub-stage 730 by the liquid supply 720, a portion of the applied ionic liquid IL and the cleaning liquid CL is drawn from one end of the tubular member. That is, the concentration measurement nozzle 740 allows recovering of a portion of the ionic liquid IL and the cleaning liquid CL applied by the liquid supply 720 onto the sub-stage 730. By performing various types of measurements on the ionic liquid IL and the cleaning liquid CL recovered by the concentration measurement nozzle 740, the concentration of the ionic liquid IL and the cleaning liquid CL can be confirmed. The various types of measurements include, for example, resistivity measurements, chromatographic measurements, and optical measurements (for example, FT-IR). In the case where the ionic liquid IL is for plating applications, the various types of measurements include colorimetric measurements and non-contact conductivity measurements.

The controller 790 controls each element of the slit coater 700. For example, the controller 790 processes a computer-executable instruction that causes the slit coater 700 to perform the wet processing performed in the atmosphere processing step S12 and the application of the liquid material containing the ionic liquid IL performed in the protective film formation step S13. The controller 790 may be configured to control the elements of the slit coater 700 to perform the wet processing in the atmosphere processing step S12 and the application of the liquid material containing the ionic liquid IL performed in the protective film formation step S13. The controller 790 includes, for example, a computer. The computer includes, for example, a CPU, a storage unit, and a communication interface.

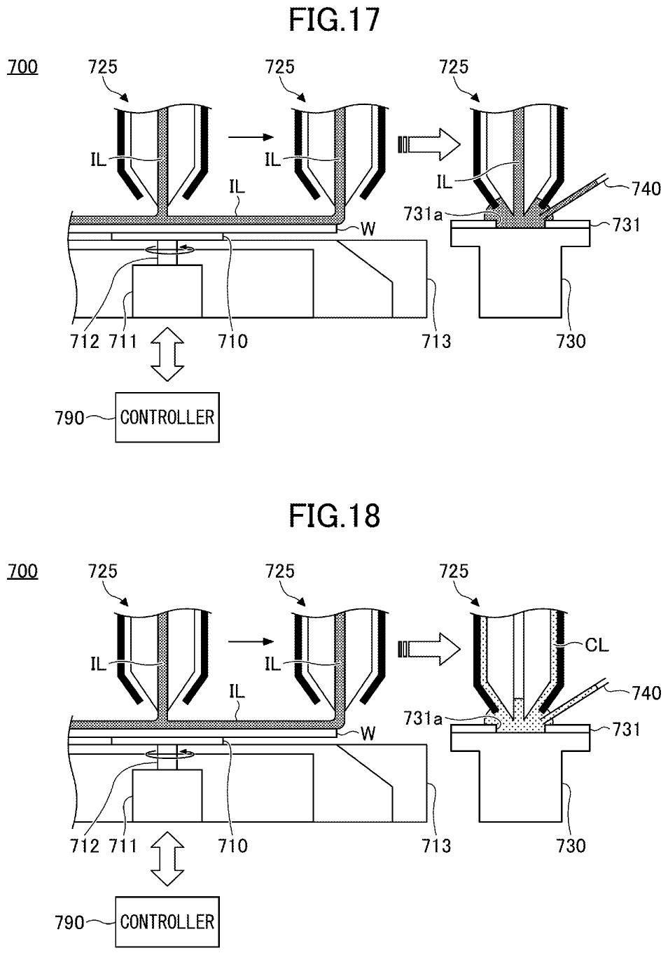

Referring to FIG. 17, an example of an operation of the slit coater 700 according to the first modification will be described. FIG. 17 is a diagram illustrating an example of an operation of the slit coater 700 according to the first modification, and illustrates an example of an operation in which the ionic liquid IL is applied to the wafer W mounted on the stage 710, and then the concentration of the ionic liquid IL is measured.

First, the controller 790 discharges the ionic liquid IL from the slit nozzle 725 to the wafer W while moving the slit nozzle 725 horizontally above the wafer W mounted on the stage 710. This causes the ionic liquid IL to be applied onto the wafer W mounted on the stage 710, as illustrated in the left of FIG. 17.

Subsequently, the controller 790 moves the slit nozzle 725 to a position above the sub-stage 730 and corresponding to the opening 731a in the plate member 731. The controller 790 discharges the ionic liquid IL from the slit nozzle 725 to the sub-stage 730. This results in the application of the ionic liquid IL on the sub-stage 730, as illustrated in the right of FIG. 17.

At this time, the ionic liquid IL discharged to the sub-stage 730 is partially absorbed by the concentration measurement nozzle 740. Therefore, by performing various measurements on the ionic liquid IL absorbed by the concentration measurement nozzle 740, the concentration of the ionic liquid IL can be confirmed.

In addition, when confirming the concentration of the ionic liquid IL, it is preferable to adjust the temperature of the sub-stage 730 in order to reduce the surface tension (viscosity) of the ionic liquid to facilitate the concentration measurement.

Referring to FIG. 18, another example of the operation of the slit coater 700 in the first modification will be described. FIG. 18 is a diagram illustrating another example of the operation of the slit coater 700 according to the first modification, and illustrates an example of an operation in which the slit nozzle 725 is automatically cleaned after the ionic liquid IL is applied to the wafer W mounted on the stage 710.

First, the controller 790 discharges the ionic liquid IL from the slit nozzle 725 to the wafer W while moving the slit nozzle 725 horizontally above the wafer W mounted on the stage 710. This causes the ionic liquid IL to be applied onto the wafer W mounted on the stage 710, as illustrated in the left of FIG. 18.

Subsequently, the controller 790 moves the slit nozzle 725 to a position above the sub-stage 730 corresponding to the opening 731a in the plate member 731. The controller 790 discharges the cleaning liquid CL from the slit nozzle 725 to the sub-stage 730. This causes the cleaning liquid CL to be applied on the sub-stage 730 and the tip of the slit nozzle 725 to be cleaned, as illustrated in the right of FIG. 18.

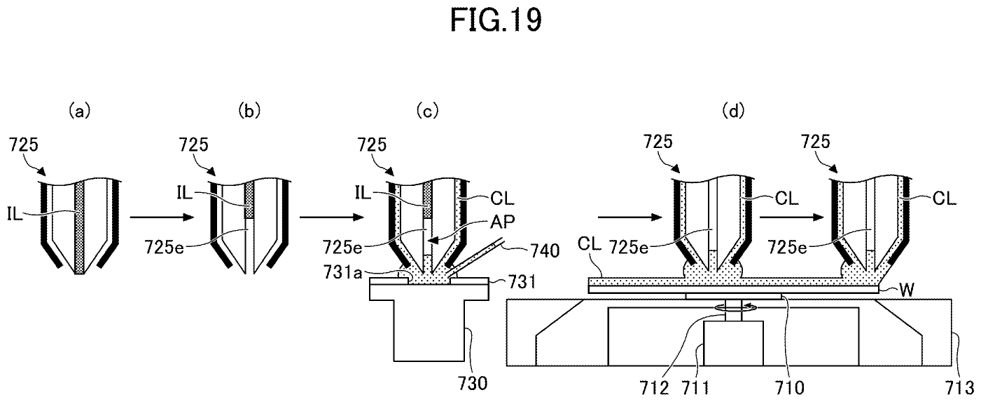

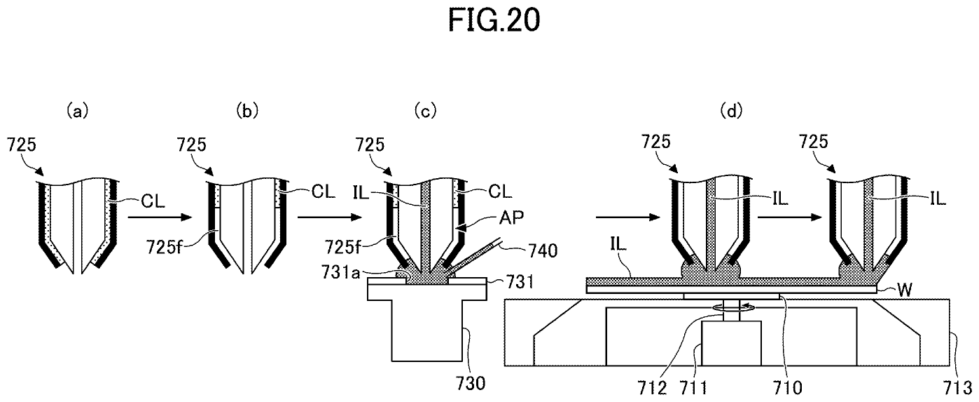

Referring to FIGS. 19 and 20, a mechanism for suppressing contact between the ionic liquid IL and the cleaning liquid CL in the slit coater 700 of the first modification will be described.

FIG. 19 is a diagram for explaining a mechanism for suppressing contact between the ionic liquid IL and the cleaning liquid CL. An example of an operation is illustrated in which the liquid material discharged from the slit nozzle 725 is switched from the ionic liquid IL to the cleaning liquid CL.

First, as illustrated in FIG. 19(a), the controller 790 stops the discharge of the ionic liquid IL by the slit nozzle 725.

Subsequently, as illustrated in FIG. 19(b), the controller 790 sucks back the ionic liquid IL upward along the ionic liquid flow path 725e by, for example, a suck-back operation.

Subsequently, as illustrated in FIG. 19(c), the controller 790 moves the slit nozzle 725 to a position above the sub-stage 730 corresponding to the opening 731a in the plate member 731. The controller 790 discharges the cleaning liquid CL from the slit nozzle 725 to the sub-stage 730. At this time, a portion of the cleaning liquid CL flows into the ionic liquid flow path 725e, but the ionic liquid IL is sucked back in the ionic liquid flow path 725e. Therefore, an air pool AP between the ionic liquid IL and the cleaning liquid CL is formed in the ionic liquid flow path 725e. As a result, mixing of the ionic liquid IL into the cleaning liquid CL can be prevented.

A portion of the cleaning liquid CL is drawn by the concentration measurement nozzle 740. By performing various measurements on the cleaning liquid CL drawn by the concentration measurement nozzle 740, the concentration of the cleaning liquid CL can be confirmed. The concentrations of the cleaning liquid CL differ between those with and without the ionic liquid IL. Therefore, by checking the concentration of the cleaning liquid CL, it is possible to check whether the ionic liquid IL is contaminated with the cleaning liquid CL.

Subsequently, as illustrated in FIG. 19(d), the controller 790 discharges the cleaning liquid CL from the slit nozzle 725 toward the wafer W while moving the slit nozzle 725 horizontally above the wafer W mounted on the stage 710. This causes the cleaning liquid CL to be applied to the wafer W mounted on the stage 710.

As described above, according to the slit coater 700 according to the first modification, when the liquid material discharged from the slit nozzle 725 is switched from the ionic liquid IL to the cleaning liquid CL, contact between the ionic liquid IL and the cleaning liquid CL can be prevented. As a result, it is possible to decrease the concentration of the cleaning liquid CL from becoming unstable after switching from the ionic liquid IL to the cleaning liquid CL.

FIG. 20 is a diagram for explaining a mechanism for preventing contact between the ionic liquid IL and the cleaning liquid CL. An example of an operation is illustrated in which the liquid material discharged from the slit nozzle 725 is switched from the cleaning liquid CL to the ionic liquid IL.

First, as illustrated in FIG. 20(a), the controller 790 stops the discharge of the cleaning liquid CL by the slit nozzle 725.

Subsequently, as illustrated in FIG. 20(b), the controller 790 sucks back the cleaning liquid CL upward along the cleaning liquid flow path 725f by, for example, a suck-back operation.

Subsequently, as illustrated in FIG. 20(c), the controller 790 moves the slit nozzle 725 to a position above the sub-stage 730 corresponding to the opening 731a in the plate member 731. The controller 790 discharges the ionic liquid IL from the slit nozzle 725 to the sub-stage 730. At this time, a portion of the ionic liquid IL flows into the cleaning liquid flow path 725f, but the cleaning liquid CL is sucked back in the cleaning liquid flow path 725f by the suck-back operation. Therefore, an air pool AP between the cleaning liquid CL and the ionic liquid IL is formed in the cleaning liquid flow path 725f. As a result, mixing of the cleaning liquid CL into the ionic liquid IL can be prevented.

A portion of the ionic liquid IL is drawn by the concentration measurement nozzle 740. By performing various measurements on the ionic liquid IL drawn by the concentration measurement nozzle 740, the concentration of the ionic liquid IL can be confirmed. The concentrations of the ionic liquid IL differ between those with and without the cleaning liquid CL. Therefore, by checking the concentration of the ionic liquid IL, it is possible to check whether or not the cleaning liquid CL is contaminated with the ionic liquid IL.

Subsequently, as illustrated in FIG. 20(d), the controller 790 discharges the ionic liquid IL from the slit nozzle 725 to the wafer W while moving the slit nozzle 725 horizontally above the wafer W mounted on the stage 710. This causes the ionic liquid IL to be applied to the wafer W mounted on the stage 710.

As described above, according to the slit coater 700 according to the first modification, when the liquid material discharged from the slit nozzle 725 is switched from the cleaning liquid CL to the ionic liquid IL, contact between the cleaning liquid CL and the ionic liquid IL can be prevented. As a result, it is possible to prevent the concentration of the ionic liquid IL from becoming unstable after switching from the cleaning liquid CL to the ionic liquid IL.

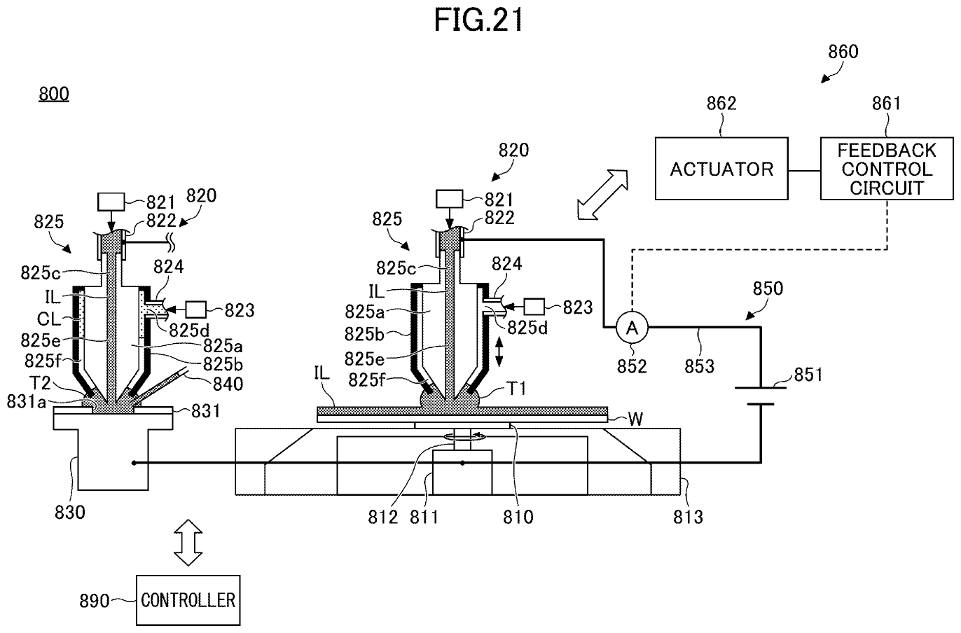

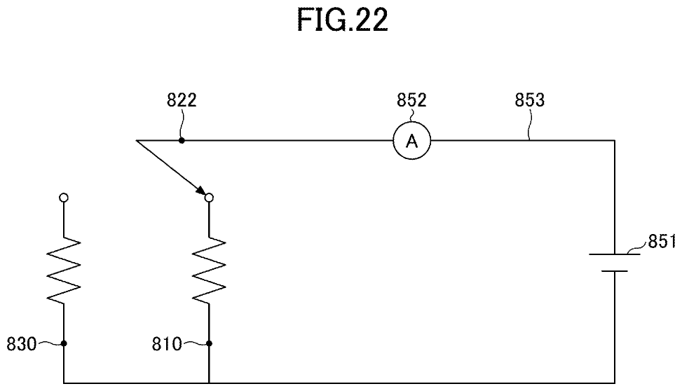

Referring to FIGS. 21 and 22, the configuration of a slit coater according to a second modification will be described. FIG. 21 is a schematic diagram illustrating the slit coater according to the second modification. FIG. 22 is an electrical circuit diagram for explaining a stage grounding circuit.

A slit coater 800 includes a stage 810, a liquid supply 820, a sub-stage 830, a concentration measurement nozzle 840, a stage grounding circuit 850, a nozzle position adjustment unit 860, and a controller 890.

The stage 810, the liquid supply 820, the sub-stage 830, the concentration measurement nozzle 840, and the controller 890 may have the same configuration as the stage 710, the liquid supply 720, the sub-stage 730, the concentration measurement nozzle 740, and the controller 790 of the slit coater 700.

The stage 810 mounts the wafer W in a substantially horizontal state. The stage 810 is connected to the upper end of a rotating shaft 812 that is rotated by a drive mechanism 811, and is configured to be rotatable. Around the lower part of the stage 810, a liquid receiver 813 whose upper side is open is provided. The liquid receiver 813 receives the liquid material and the like that drops off or is shaken off the wafer W.

The liquid supply 820 includes an ionic liquid supply 821, an ionic liquid supply pipe 822, a cleaning liquid supply 823, a cleaning liquid supply pipe 824, and a slit nozzle 825. The slit nozzle 825 has a body 825a, an outer skin 825b, an ionic liquid supply port 825c, a cleaning liquid supply port 825d, an ionic liquid flow path 825e, and a cleaning liquid flow path 825f.

On the upper surface of the sub-stage 830, a plate member 831 having an opening 831a in the region where the ionic liquid IL and the cleaning liquid CL are applied, is provided.

The stage grounding circuit 850 includes a power supply 851, an ammeter 852, and a wiring 853.

The power supply 851 applies a DC voltage between the ionic liquid supply pipe 822 and the stage 810 via the wiring 853. This allows a small current to flow from the ionic liquid supply pipe 822 through the ionic liquid IL to the stage 810. The power supply 851 also applies a DC voltage between the ionic liquid supply pipe 822 and the sub-stage 830 via the wiring 853. This allows a small current to flow from the ionic liquid supply pipe 822 through the ionic liquid IL to the sub-stage 830. The power supply 851 may superimpose the alternating current (AC) component on the DC voltage.

The ammeter 852 is interposed with the wiring 853. The ammeter 852 measures the minute current flowing from the ionic liquid supply pipe 822 through the ionic liquid IL into the stage 810. The value of the microcurrent changes depending on the volume of a liquid filling T1 formed by the ionic liquid IL on the wafer W mounted on the stage 810. Therefore, by monitoring the value of the minute current measured by the ammeter 852, the volume of the liquid filling T1 formed by the ionic liquid IL on the wafer W can be determined. The ammeter 852 also measures the minute current flowing from the ionic liquid supply pipe 822 through the ionic liquid IL into the sub-stage 830. The value of the microcurrent changes depending on the volume of the liquid filling T2 formed by the ionic liquid IL on the sub-stage 830. Therefore, by monitoring the value of the minute current measured by the ammeter 852, the volume of the liquid filling T2 formed by the ionic liquid IL on the sub-stage 830 can be determined.

The wiring 853 electrically connects the power supply 851 to the ionic liquid supply pipe 822, stage 810, and sub-stage 830.

The nozzle position adjustment unit 860 controls the height position of the slit nozzle 825 such that the volume of the liquid filling T1 formed by the ionic liquid IL on the wafer W mounted on the stage 810 is constant based on the measured value of the ammeter 852. The nozzle position adjustment unit 860 also controls the height position of the slit nozzle 825 such that the volume of the liquid filling T2 formed by the ionic liquid IL on the sub-stage 830 is constant based on the measured value of the ammeter 852. The nozzle position adjustment unit 860 may also control the height position of the slit nozzle 825 based on the resistance value of the ionic liquid IL calculated based on the DC voltage applied by the power supply 851 and the minute current measured by the ammeter 852. The nozzle position adjustment unit 860 includes a feedback control circuit 861 and an actuator 862.

The feedback control circuit 861 controls the actuator 862 based on the measured value of the ammeter 852. For example, the feedback control circuit 861 controls the actuator 862 so that the measured value of the ammeter 852 is constant. This allows the distance between the upper surface of the wafer W and the tip of the slit nozzle 825 to be maintained approximately constant. The distance between the upper surface of the sub-stage 830 and the tip of the slit nozzle 825 can also be maintained approximately constant. The feedback control circuit 861 may be included in the controller 890.

The actuator 862 raises and lowers the slit nozzle 825 based on the signals from the feedback control circuit 861.

As described above, according to the slit coater 800 according to the second modification, the nozzle position adjustment unit 860 controls the height position of the slit nozzle 825 such that the volume of the liquid filling T1 on the wafer W mounted on the stage 810 is constant based on the measured value of the ammeter 852. This allows the ionic liquid IL to be applied from the slit nozzle 825 onto the wafer W while maintaining a substantially constant distance between the upper surface of the wafer W and the tip of the slit nozzle 825. As a result, the in-plane uniformity of the thickness of the ionic liquid IL applied on the wafer W is improved.

According to the slit coater 800 according to the second modification, the nozzle position adjustment unit 860 controls the height position of the slit nozzle 825 so that the volume of the liquid filling T2 on the sub-stage 830 is constant based on the measured value of the ammeter 852. This allows the ionic liquid IL to be applied from the slit nozzle 825 to the sub-stage 830 while maintaining a substantially constant distance between the upper surface of the sub-stage 830 and the tip of the slit nozzle 825.

Also, according to the slit coater 800 of the second modification, the power supply 851 is provided for applying a DC voltage between the ionic liquid supply pipe 822 and the stage 810. Thus, electrolytic plating can be performed using the slit coater 800 by applying a DC voltage between the ionic liquid supply pipe 822 and the stage 819 by the power supply 851 while supplying the ionic liquid IL for plating application from the slit nozzle 825.

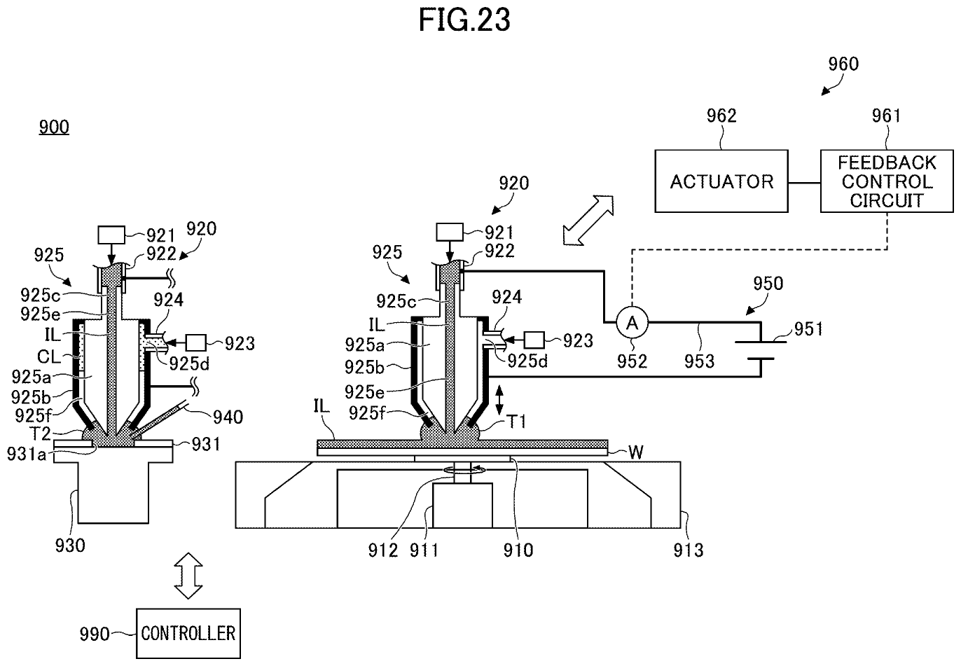

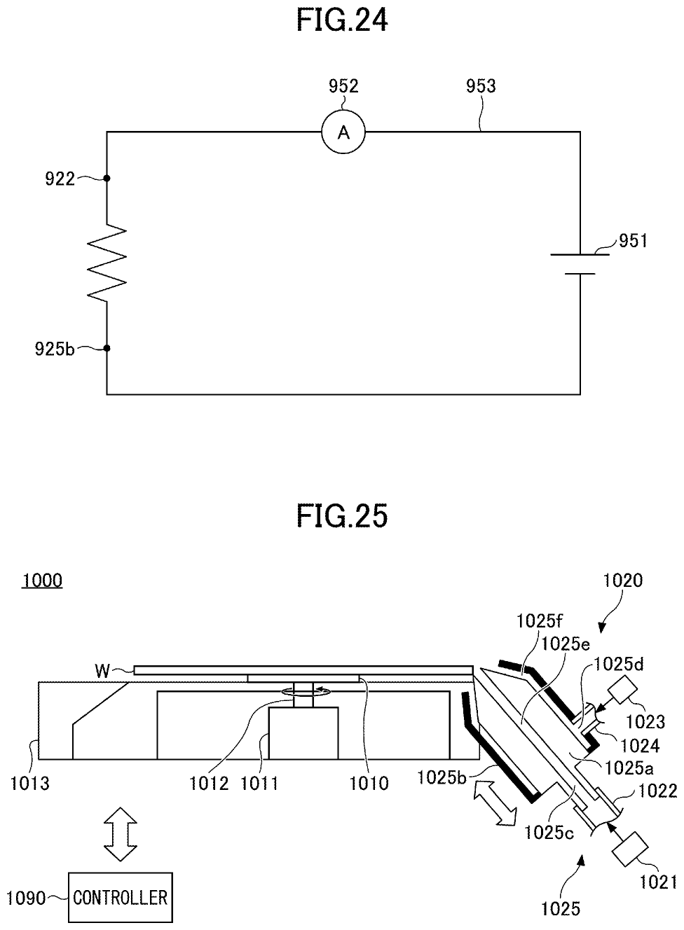

Referring to FIGS. 23 and 24, the configuration of a slit coater according to a third modification will be described. FIG. 23 is a schematic diagram illustrating the slit coater according to the third modification. FIG. 24 is an electrical circuit diagram for illustrating an outer skin grounding circuit.

A slit coater 900 includes a stage 910, a liquid supply 920, a sub-stage 930, a concentration measurement nozzle 940, an outer skin grounding circuit 950, a nozzle position adjustment unit 960, and a controller 990.

The stage 910, the liquid supply 920, the sub-stage 930, the concentration measurement nozzle 940, and the controller 990 may have the same configuration as the stage 710, the liquid supply 720, the sub-stage 730, the concentration measurement nozzle 740, and the controller 790 of the slit coater 700.

The stage 910 mounts the wafer W in a substantially horizontally state. The stage 910 is connected to the upper end of a rotating shaft 912 which is rotated by a drive mechanism 911 and is configured to be rotatable. Around the lower part of the stage 910, a liquid receiver 913 whose upper side is open is provided. The liquid receiver 913 receives the liquid material and the like that drops off or is shaken off the wafer W.

The liquid supply 920 includes an ionic liquid supply 921, an ionic liquid supply pipe 922, a cleaning liquid supply pipe 923, a cleaning liquid supply pipe 924, and a slit nozzle 925. The slit nozzle 925 has a body 925a, an outer skin 925b, an ionic liquid supply port 925c, a cleaning liquid supply port 925d, an ionic liquid flow path 925e, and a cleaning liquid flow path 925f.

On the upper surface of the sub-stage 930, a plate-like member 931 having openings 931a in the region where the ionic liquid IL and the cleaning liquid CL are applied, is provided.

The outer skin grounding circuit 950 includes a power supply 951, an ammeter 952, and a wiring 953.

The power supply 951 applies a DC voltage between the ionic liquid supply pipe 922 and the outer skin 925b via the wiring 953. This allows a small current to flow from the ionic liquid supply pipe 922 through the ionic liquid IL to the outer skin 925b. The power supply 951 may superimpose the AC component on the DC voltage.

The ammeter 952 is interposed on the wiring 953. The ammeter 952 measures the minute current flowing from the ionic liquid supply pipe 922 through the ionic liquid IL to the outer skin 925b. The value of the microcurrent changes depending on the volume of the liquid filling T1 formed by the ionic liquid IL on the wafer W mounted on the stage 910. Therefore, by monitoring the value of the minute current measured by the ammeter 952, the volume of the liquid filling T1 formed by the ionic liquid IL on the wafer W can be measured. The value of the microcurrent also changes depending on the volume of the liquid filling T2 formed by the ionic liquid IL on the sub-stage 930. Therefore, by monitoring the value of the minute current measured by the ammeter 952, the volume of the liquid filling T2 formed by the ionic liquid IL on the sub-stage 930 can be determined.

The wiring 953 electrically connects the power supply 951 to the ionic liquid supply pipe 922 and outer skin 925b.

The nozzle position adjustment unit 960 controls the height position of the slit nozzle 925 such that the volume of the liquid filling T1 formed by the ionic liquid IL on the wafer W mounted on the stage 910 is constant based on the measured value of the ammeter 952. The nozzle position adjustment unit 960 controls the height position of the slit nozzle 925 so that the volume of the liquid filling T2 formed by the ionic liquid IL on the sub-stage 930 is constant based on the measured value of the ammeter 952. The nozzle position adjustment unit 960 may control the height position of the slit nozzle 925 based on the resistance value of the ionic liquid IL calculated based on the DC voltage applied by the power supply 951 and the minute current measured by the ammeter 952. The nozzle position adjustment unit 960 includes a feedback control circuit 961 and an actuator 962.

The feedback control circuit 961 controls the actuator 962 based on the measured value of the ammeter 952. For example, the feedback control circuit 961 controls the actuator 962 so that the measured value of the ammeter 952 is constant. This allows the distance between the upper surface of the wafer W and the tip of the slit nozzle 925 to be maintained approximately constant. The distance between the upper surface of the sub-stage 930 and the tip of the slit nozzle 925 can be maintained approximately constant. The feedback control circuit 961 may be included in the controller 990.

The actuator 962 raises and lowers the slit nozzle 925 based on the signals from the feedback control circuit 961.

As described above, according to the slit coater 900 according to the third modification, the nozzle position adjustment unit 960 controls the height position of the slit nozzle 925 so that the volume of the liquid filling T1 on the wafer W mounted on the stage 910 is constant based on the measured value of the ammeter 952. This allows the ionic liquid IL to be applied from the slit nozzle 925 onto the wafer W while maintaining a substantially constant distance between the upper surface of the wafer W and the tip of the slit nozzle 925. As a result, the in-plane uniformity of the thickness of the ionic liquid IL applied on the wafer W is improved.

According to the slit coater 900 according to the third modification, the nozzle position adjustment unit 960 controls the height position of the slit nozzle 925 so that the volume of the liquid filling T2 on the sub-stage 930 is constant based on the measured value of the ammeter 952. Thus, the ionic liquid IL can be applied from the slit nozzle 925 to the sub-stage 930 while maintaining a substantially constant distance between the upper surface of the sub-stage 930 and the tip of the slit nozzle 925.

Referring to FIG. 25, a configuration of a slit coater according to a fourth modification will be described. FIG. 25 is a schematic diagram illustrating the slit coater according to the fourth modification.

A slit coater 1000 includes a stage 1010, an end liquid supply 1020, and a controller 1090.

The stage 1010 and the controller 1090 may have the same configuration as the stage 701 and the controller 790 of the slit coater 700.

The stage 1010 mounts the wafer W in a substantially horizontal state. The stage 1010 is connected to the upper end of a rotating shaft 1012 that is rotated by a drive mechanism 1011, and is configured to be rotatable. Around the lower part of the stage 1010, a liquid receiver 1013 whose upper side is open is provided. The liquid receiver 1013 receives the liquid material and the like that drops off or is shaken off the wafer W.

The end liquid supply 1020 applies the liquid material to the end of the wafer W. The end liquid supply 1020 includes an ionic liquid supply 1021, an ionic liquid supply pipe 1022, a cleaning liquid supply 1023, a cleaning liquid supply pipe 1024, and a slit nozzle 1025.

The ionic liquid supply 1021, the ionic liquid supply pipe 1022, the cleaning liquid supply 1023, and the cleaning liquid supply pipe 1024 may have the same configuration as the ionic liquid supply 721, the ionic liquid supply pipe 722, the cleaning liquid supply 723, and the cleaning liquid supply pipe 724.

The slit nozzle 1025 is configured to be movable between a position close to the wafer W and a position separated from the wafer W on the side of the wafer W. The slit nozzle 1025 moves to the position close to the wafer W to supply the ionic liquid IL and the cleaning liquid CL to the end of the wafer W mounted on the stage 1010. The slit nozzle 1025 includes a body 1025a, an outer skin 1025b, an ionic liquid supply port 1025c, a cleaning liquid supply port 1025d, an ionic liquid flow path 1025e, and a cleaning liquid flow path 1025f.

The body 1025a, the outer skin 1025b, the ionic liquid supply port 1025c, the cleaning liquid supply port 1025d, the ionic liquid flow path 1025e, and the cleaning liquid flow path 1025f may have the same configuration as the body 725a, the outer skin 725b, the ionic liquid supply port 725c, the cleaning liquid supply port 725d, the ionic liquid flow path 725e, and the cleaning liquid flow path 725f of the slit nozzle 725.

The slit nozzle 1025 may be configured to supply the ionic liquid IL and the cleaning liquid CL to the surface of the wafer W mounted on the stage 1010 by moving the upper portion of the wafer W horizontally.

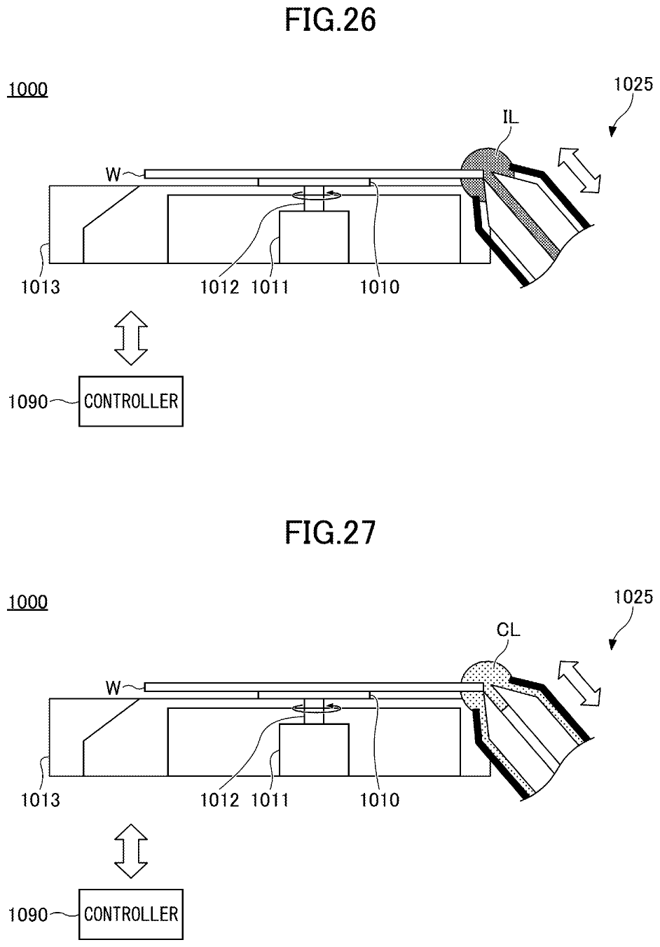

Referring to FIG. 26, an example of an operation of the slit coater 1000 according to the fourth modification will be described. FIG. 26 is a diagram illustrating an example of the operation of the slit coater 1000 according to the fourth modification, and illustrates an example of an operation when the ionic liquid IL is applied to the end of the wafer W mounted on the stage 1010.

When the ionic liquid IL is applied to the end of the wafer W mounted on the stage 1010, the controller 1090 moves the slit nozzle 1025 closer to the wafer W, as illustrated in FIG. 26. Subsequently, the controller 1090 rotates the wafer W, mounted on the stage 1010, and the stage 1010, by the drive mechanism 1011 via the rotating shaft 1012, while discharging the ionic liquid IL from the slit nozzle 1025 toward the end of the wafer W. This causes the ionic liquid IL to be applied throughout the entire circumference of the end of the wafer W mounted on the stage 1010.

Referring to FIG. 27, another example of the operation of the slit coater 1000 according to the fourth modification will be described. FIG. 27 is a diagram illustrating another example of the operation of the slit coater 1000 according to the fourth modification, and illustrates an example of the operation when the cleaning liquid CL is applied to the end of the wafer W mounted on the stage 1010.

When the cleaning liquid CL is applied to the end of the wafer W mounted on the stage 1010, the controller 1090 moves the slit nozzle 1025 to the position close to the wafer W, as illustrated in FIG. 27. Subsequently, the controller 1090 rotates the wafer W, mounted on the stage 1010, and the stage 1010, by a drive mechanism 1011 via a rotating shaft 1012, while discharging the cleaning liquid CL from the slit nozzle 1025 toward the end of the wafer W. This causes the cleaning liquid CL to be applied throughout the entire circumference of the end of the wafer W mounted on the stage 1010.

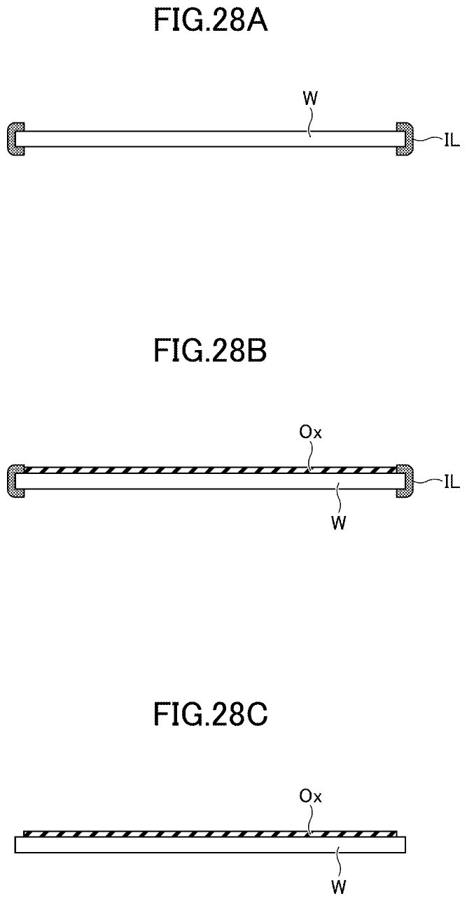

Referring to FIGS. 28A to 28C, an application of the slit coater 1000 in a fourth modification will be described. FIGS. 28A to 28C are diagrams illustrating an application of the slit coater 1000 according to the fourth modification. Hereinafter, as an application example of the slit coater 1000, a film-forming method of depositing an oxide film on the wafer W will be described.

First, as illustrated in FIG. 28A, the ionic liquid IL is selectively applied to the end of the wafer W by the slit coater 1000 (an ionic liquid application step). As the ionic liquid IL, the ionic liquid in which an element that inhibits the adsorption of a precursor is coordinated to a surface, that is used in the deposition step described below, can be used. The elements include, for example, halogens such as fluorine (F), chlorine (Cl), bromine (Br), iodine (I), astatine (At), and tennessine (Ts). Subsequently, as illustrated in FIG. 28B, an oxide film Ox is deposited on the wafer W on which the ionic liquid IL is applied at the end in the ionic liquid application step, by a vacuum deposition device (for example, the vacuum deposition device 100 described above) (a deposition process). Examples of a method of depositing the oxide film Ox include atomic layer deposition (ALD) and chemical vapor deposition (CVD). In the film formation process, when O—H groups are present on the surface of the wafer W, an oxide film is deposited by adsorption of the precursor to them. However, the halogen described above prevents adsorption of the precursor by replacing the O—H group on the surface of the wafer W. Therefore, the oxide film Ox is not deposited at the end of the wafer W, or is deposited only slightly.

Then, the cleaning liquid CL is selectively applied to the end of the wafer W by the slit coater 1000 (the cleaning liquid application step). This allows the ionic liquid IL applied to the end of the wafer W to be washed away by the cleaning liquid CL, as illustrated in FIG. 28C. As a result, the oxide film Ox remains in the region other than the end of the wafer W. In this case, even when the oxide film Ox is slightly deposited on the ionic liquid IL at the end of the wafer W in the deposition step, the oxide film Ox is washed away together with the ionic liquid IL. The cleaning liquid CL is preferably a liquid material commonly used in semiconductor cleaning processes, including isopropyl alcohol (IPA), but may be a cleaning agent used in other semiconductor processes (for example, an acidic cleaning agent such as phosphoric acid, hydrofluoric acid, hydrochloric acid, nitric acid, and the like, or an alkaline cleaning agent such as SC1 (NH₄OH/H₂O₂/H₂O)).

According to the deposition method described above, because the deposition to the end (for example, the bevel part) of the wafer W can be prevented, dust generation from the end of the wafer W can be reduced.

In the example of FIGS. 28A to 28C, the case in which the oxide film Ox is deposited on the wafer W has been described as an example, but this is not limiting. For example, the above can be applied to the case where a nitride film is formed on the wafer W. In this case, the halogen prevents the precursor adsorption by replacing the N—H group on the surface of the wafer W.

In the slit coater 1000 according to the fourth modification, a stage grounding circuit and a nozzle position adjustment unit similar to the stage grounding circuit 850 and the nozzle position adjustment unit 860 of the slit coater 800 of the second modification may be provided. Thus, the ionic liquid IL can be applied from the slit nozzle 1025 to the end of the wafer W while maintaining a substantially constant distance between the end of the wafer W and the tip of the slit nozzle 1025. As a result, the circumferential uniformity of the thickness of the ionic liquid IL applied to the end of the wafer W is improved.

In the slit coater 1000 according to the fourth modification, an outer skin grounding circuit and a nozzle position adjustment unit similar to the outer skin grounding circuit 950 and the nozzle position adjustment unit 960 of the slit coater 900 of the third modification may be provided. Thus, the ionic liquid IL can be applied from the slit nozzle 1025 to the end of the wafer W while maintaining a substantially constant distance between the end of the wafer W and the tip of the slit nozzle 1025. As a result, the circumferential uniformity of the thickness of the ionic liquid IL applied to the end of the wafer W is improved.

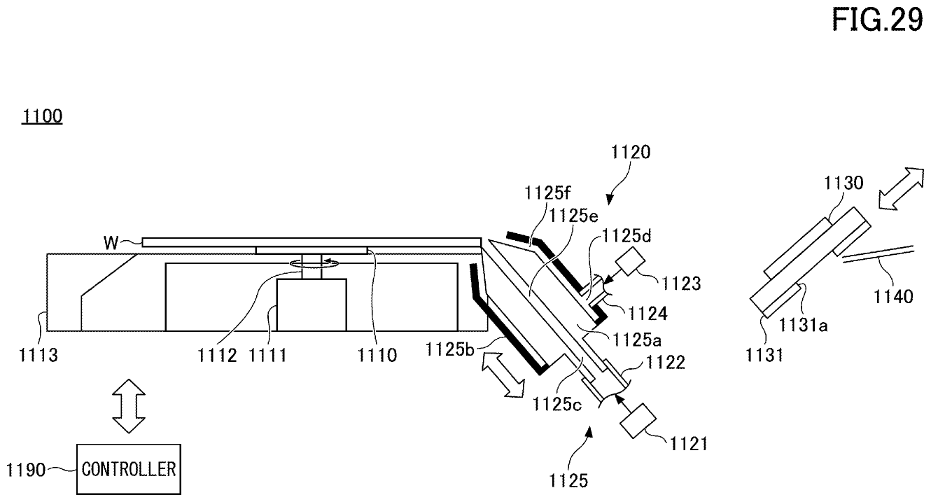

Referring to FIG. 29, a configuration of a slit coater according to a fifth modification will be described. FIG. 29 is a schematic diagram illustrating the slit coater according to the fifth modification.

A slit coater 1100 includes a stage 1110, an end liquid supply 1120, a sub-stage 1130, a concentration measurement nozzle 1140, and a controller 1190.

The stage 1110 and the controller 1190 may have the same configuration as the stage 710 and the controller 790 of the slit coater 700.

The stage 1110 mounts the wafer W in a substantially horizontal state. The stage 1110 is connected to the upper end of a rotating shaft 1112 that is rotated by a drive mechanism 1111, and is configured to be rotatable. Around the lower part of the stage 1110, a liquid receiver 1113 whose upper side is open is provided. The liquid receiver 1113 receives the liquid material and the like that drops off or is shaken off the wafer W.

The end liquid supply 1120 applies the liquid material to the end of the wafer W. The end liquid supply 1120 includes an ionic liquid supply 1121, an ionic liquid supply pipe 1122, a cleaning liquid supply 1123, a cleaning liquid supply pipe 1124, and a slit nozzle 1125. The ionic liquid supply 1121, the ionic liquid supply pipe 1122, the cleaning liquid supply 1123, the cleaning liquid supply pipe 1124, and the slit nozzle 1125 may be the same configuration as the ionic liquid supply 1021, the ionic liquid supply pipe 1022, the cleaning liquid supply 1023, the cleaning liquid supply pipe 1024, and the slit nozzle 1025 of the slit coater 1000.

The slit nozzle 1125 includes a body 1125a, an outer skin 1125b, an ionic liquid supply port 1125c, a cleaning liquid supply port 1125d, an ionic liquid flow path 1125e, and a cleaning liquid flow path 1125f. The body 1125a, the outer skin 1125b, the ionic liquid supply port 1125c, the cleaning liquid supply port 1125d, the ionic liquid flow path 1125e, and the cleaning liquid flow path 1125f may have the same configuration as the body 725a, the outer skin 725b, the ionic liquid supply port 725c, the cleaning liquid supply port 725d, the ionic liquid flow path 725e, and the cleaning liquid flow path 725f of the slit nozzle 725.

The sub-stage 1130 is provided in a position where the end liquid supply 1120 can apply the ionic liquid IL and the cleaning liquid CL, apart from the stage 1110. The sub-stage 1130 is configured to move between an application position and a retracted position. The application position is where the slit nozzle 1125 can apply the liquid material to the application surface of the sub-stage 1130 when the slit nozzle 1125 moves away from the wafer W. The retracted position is one in which the slit nozzle 1125 does not contact the slit nozzle 1125 when moving between a position close to the wafer W and a position spaced from the wafer W. FIG. 29 illustrates a state in which the sub-stage 1130 is moved to the retracted position. The application surface of the sub-stage 1130 is provided with a plate member 1131 having an opening 1131a in the region where the ionic liquid IL and the cleaning liquid CL are applied. The sub-stage 1130 is adapted to adjust the temperature of the application surface by heating means or cooling means. The heating means may be, for example, a heater embedded within the sub-stage 1130. The cooling means may be, for example, a refrigerant flow path formed within the sub-stage 1130.

The concentration measurement nozzle 1140 is formed of, for example, a tubular member. The concentration measurement nozzle 1140 is provided at a position where one end contacts the ionic liquid IL and the cleaning liquid CL applied to the application surface of the sub-stage 1130. Accordingly, when the ionic liquid IL and the cleaning liquid CL are applied to the application surface of the sub-stage 1130 by the end liquid supply 1120, a portion of the applied ionic liquid IL and cleaning liquid CL is drawn from one end of the tubular member. That is, the concentration measurement nozzle 1140 allows recovering of a portion of the ionic liquid IL and the cleaning liquid CL applied to the application surface of the sub-stage 1130 by the end liquid supply 1120. By performing various types of measurements on the ionic liquid IL and the cleaning liquid CL recovered by the concentration measurement nozzle 1140, the concentration of the ionic liquid IL and the cleaning liquid CL can be confirmed. The various types of measurements include, for example, resistivity measurements, chromatographic measurements, and optical measurements (for example, FT-IR). In the case where the ionic liquid IL is for plating applications, the various types of measurements include colorimetric measurements and non-contact conductivity measurements.

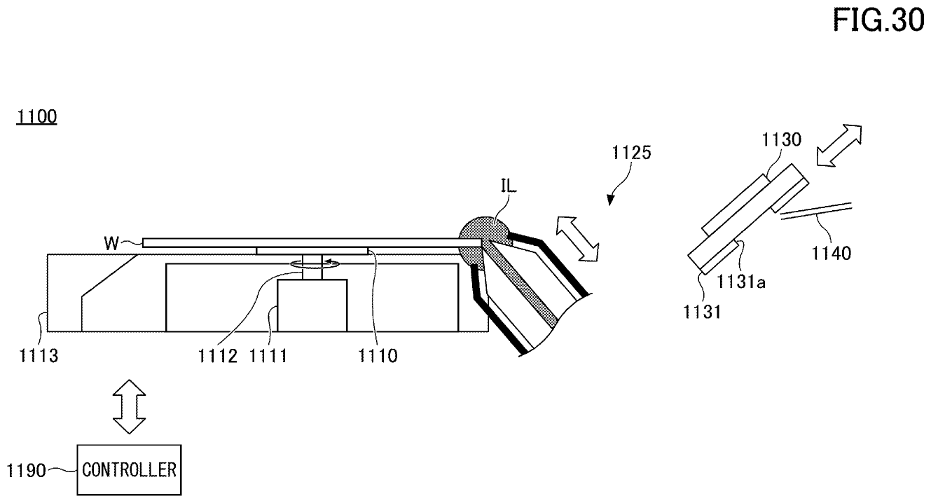

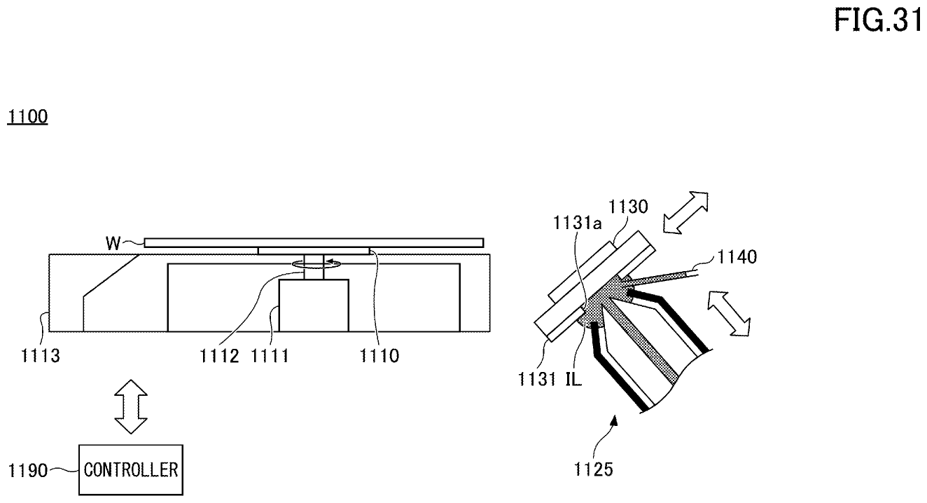

Referring to FIGS. 30 and 31, an example of an operation of the slit coater 1100 according to a fifth modification will be described. FIGS. 30 and 31 are diagrams illustrating an example of an operation of the slit coater 1100 according to the fifth modification, and an example of an operation in which the ionic liquid IL is applied to the end of the wafer W mounted on the stage 1110, and then the concentration of the ionic liquid IL is measured.

First, as illustrated in FIG. 30, the controller 1190 moves the slit nozzle 1125 to the location closer to the wafer W. Subsequently, the controller 1190 rotates the wafer W, mounted on the stage 1110, and the stage 1110 via the rotating shaft 1112 by the drive mechanism 1111 while discharging the ionic liquid IL from the slit nozzle 1125 toward the end of the wafer W. This causes the ionic liquid IL to be applied throughout the entire circumference of the end of the wafer W mounted on the stage 1110.

Subsequently, as illustrated in FIG. 31, the controller 1190 moves the slit nozzle 1125 to the location spaced from the wafer W, and moves the sub-stage 1130 from the retracted position to the application position. The controller 1190 discharges the ionic liquid IL from the slit nozzle 1125 toward the sub-stage 1130. This causes the ionic liquid IL to be applied onto the sub-stage 1130.

At this time, the ionic liquid IL discharged to the sub-stage 1130 is partially absorbed by the concentration measurement nozzle 1140. Therefore, by performing the various types of measurements on the ionic liquid IL absorbed by the concentration measurement nozzle 1140, the concentration of the ionic liquid IL can be confirmed.

In addition, when confirming the concentration of the ionic liquid IL, it is preferable to adjust the temperature of the sub-stage 1130 in order to reduce the surface tension (viscosity) of the ionic liquid IL to facilitate the concentration measurement.

Further, in the slit coater 1100 according to the fifth modification, a stage grounding circuit and a nozzle position adjustment unit similar to the stage grounding circuit 850 and the nozzle position adjustment unit 860 of the slit coater 800 of the second modification may be provided. Thus, the ionic liquid IL can be applied from the slit nozzle 1125 to the end of the wafer W while maintaining a substantially constant distance between the end of the wafer W and the tip of the slit nozzle 1125. As a result, the circumferential uniformity of the thickness of the ionic liquid IL applied to the end of the wafer W is improved.

Further, in the slit coater 1100 according to the fifth modification, an outer skin grounding circuit and a nozzle position adjustment unit similar to the outer skin ground circuit 950 and the nozzle position adjustment unit 960 of the slit coater 900 of the third modification may be provided. Thus, the ionic liquid IL can be applied from the slit nozzle 1125 to the end of the wafer W while maintaining a substantially constant distance between the end of the wafer W and the tip of the slit nozzle 1125. As a result, the circumferential uniformity of the thickness of the ionic liquid IL applied to the end of the wafer W is improved.

The embodiments disclosed herein should be considered to be exemplary in all respects and not limiting. The above embodiments may be omitted, substituted, or changed in various forms without departing from the appended claims and spirit thereof.

With reference to the above embodiments, the following appendix is further disclosed.
(Appendix 1)

A method of manufacturing a semiconductor device, the method including:

applying a liquid material containing an ionic liquid on a substrate to form a protective film;

transferring at an atmosphere the substrate on which the protective film is formed; and

removing the protective film from the substrate that has been transferred at the atmosphere.
(Appendix 2)

The method of Appendix 1, wherein forming the protective film is performed at the atmosphere.
(Appendix 3)

The method of Appendix 1, wherein forming the protective film is performed in a vacuum.
(Appendix 4)

The method of any one of Appendices 1 to 3, wherein removing the protective film is performed in a vacuum.
(Appendix 5)

The method of Appendix 4, further including, after removing the protective film, forming a film on the substrate in a vacuum without exposing the substrate to an atmosphere.
(Appendix 6)

The method of any one of Appendices 1 to 3, wherein removing the protective film is performed at the atmosphere.
(Appendix 7)

The method of Appendix 6, further including, after removing the protective film, forming a film on the substrate at the atmosphere.
(Appendix 8)

The method of Appendix 7, wherein in forming the film, the film is formed by a plating method.
(Appendix 9)

The method of Appendices 1 to 8, further including, before forming the protective film, removing an oxide generated on the substrate.
(Appendix 10)

The method of Appendix 9, wherein removing the oxide is performed at the atmosphere.
(Appendix 11)

The method of Appendix 10, wherein removing the oxide includes removing the oxide with a chemical solution containing hydrogen fluoride (HF).
(Appendix 12)

The method of Appendix 9, wherein removing the oxide is performed in a vacuum.
(Appendix 13)

The method of Appendix 12, wherein removing the oxide includes:

supplying a mixed gas containing a gas containing a halogen element and a basic gas to the substrate to transform the oxide to generate a reaction product; and

removing the reaction product.
(Appendix 14)

The method of any one of Appendices 1 to 13, wherein a physical property of the ionic liquid changes depending on an environmental factor.
(Appendix 15)

The method of Appendix 14, wherein the environmental factor includes temperature.
(Appendix 16)

The method of Appendix 14 or 15, wherein the physical property includes at least one of viscosity and adhesiveness.
(Appendix 17)

The method of any one of Appendices 1 to 16, wherein the ionic liquid has a property of not evaporating in a vacuum.
(Appendix 18)

The method of any one of Appendices 1 to 17, wherein the substrate has a region where a conductive material is exposed on a surface.
(Appendix 19)

A semiconductor manufacturing device including:

a first processing module configured to apply a liquid material containing an ionic liquid on a substrate to form a protective film;

a second processing module configured to remove the protective film formed on the substrate; and

a transfer module configured to transfer at an atmosphere the substrate between the first processing module and the second processing module.
(Appendix 20)

A system including:

a first processing device configured to apply a liquid material containing an ionic liquid on a substrate to form a protective film;

a second processing device configured to remove the protective film formed on the substrate; and

a transfer device configured to transfer at an atmosphere the substrate between the first processing device and the second processing device.
(Appendix 21)

An application device including:

a stage configured to be mounted with a substrate; and

a liquid supply configured to apply a liquid material to a surface of the substrate mounted on the stage, wherein

the liquid supply includes an ionic liquid flow path configured to discharge an ionic liquid and a cleaning liquid flow path configured to discharge a cleaning liquid.
(Appendix 22)

The application device of Appendix 21, wherein the cleaning liquid flow path is provided around the ionic liquid flow path.
(Appendix 23)

The application device of Appendix 21 or 22, further including, aside from the stage, a sub-stage at a position where the liquid material can be applied by the liquid supply.
(Appendix 24)

The application device of Appendix 23, wherein the sub-stage is capable of adjusting the temperature of a surface to which the liquid material is applied.
(Appendix 25)

The application device of Appendix 23 or 24, further including a concentration measurement nozzle configured to recover a portion of the liquid material applied to the sub-stage.
(Appendix 26)

The application device of Appendix 25, wherein the concentration measurement nozzle is formed of a tubular member, and one end of the tubular member is provided at a position where the one end of the tubular member contacts the liquid material applied to the sub-stage.
(Appendix 27)

The application device of any one of Appendices 21 to 26, further including a measurement unit configured to measure a resistance value of the liquid material applied to a surface of the substrate placed on the stage by the liquid supply.
(Appendix 28)

The application device of Appendix 27, further including a position adjustment unit configured to control a height position of the liquid supply based on the resistance value measured by the measurement unit.
(Appendix 29)

The application device of Appendix 28, wherein the position adjustment unit is configured to control the height position of the liquid supply so that the resistance value measured by the measurement unit is constant.
(Appendix 30)

The application device of Appendix 28 or 29, wherein the position adjustment unit includes:

an actuator configured to raise and lower the liquid supply; and

a feedback control circuit configured to control the actuator based on the resistance value measured by the measurement unit.
(Appendix 31)

An application device including:

a rotatable stage configured to be mounted with a substrate; and

an end liquid supply configured to apply a liquid material to an end of the substrate mounted on the stage, wherein

the end liquid supply includes an ionic liquid flow path configured to discharge an ionic liquid and a cleaning liquid flow path configured to discharge a cleaning liquid.
(Appendix 32)

The application device of Appendix 31, wherein the cleaning liquid flow path is provided around the ionic liquid flow path.
(Appendix 33)

The application device of Appendix 31 or 32, further including, aside from the stage, a sub-stage at a position where the liquid material can be applied by the end liquid supply.
(Appendix 34)

The application device of Appendix 33, wherein the sub-stage is capable of adjusting the temperature of a surface to which the liquid material is applied.
(Appendix 35)

The application device of Appendix 33 or 34, further including a concentration measurement nozzle configured to recover a portion of the liquid material applied to the sub-stage.
(Appendix 36)

The application device of Appendix 35, wherein the concentration measurement nozzle is formed of a tubular member, and one end of the tubular member is provided at a position where the one end of the tubular member contacts the liquid material applied to the sub-stage.
(Appendix 37)

The application device of any one of Appendices 31 to 36, further including a measurement unit configured to measure a resistance value of the liquid material applied to a surface of the substrate placed on the stage by the end liquid supply.
(Appendix 38)

The application device of Appendix 37, further including a position adjustment unit configured to control a height position of the end liquid supply based on the resistance value measured by the measurement unit.
(Appendix 39)

The application device of Appendix 38, wherein the position adjustment unit is configured to control the height position of the end liquid supply so that the resistance value measured by the measurement unit is constant.
(Appendix 40)

The application device of Appendix 38 or 39, wherein the position adjustment unit includes:

an actuator configured to raise and lower the end liquid supply; and

a feedback control circuit configured to control the actuator based on the resistance value measured by the measurement unit.
(Appendix 41)

A method of manufacturing a semiconductor device, the method including:

applying a liquid material containing an ionic liquid to an end of a substrate;

supplying a precursor to the substrate in which the ionic liquid is applied to the end thereof to deposit an oxide film or a nitride film; and

selectively applying a cleaning liquid for removing the ionic liquid to the end of the substrate on which the oxide film or the nitride film is deposited, wherein

the ionic liquid contains an element that inhibits adsorption of the precursor.

The present application claims priority to Japanese Patent Application No. 2020-079705, filed Apr. 28, 2020, and Japanese Patent Application No. 2020-212880 filed Dec. 22, 2020, with the Japanese Patent Office, the contents of which are incorporated herein by reference in their entirety.

### DESCRIPTION OF THE REFERENCE NUMERAL

10 Substrate

14 Protective film

1. A method of manufacturing a semiconductor device, the method comprising:
applying a liquid material containing an ionic liquid on a substrate to form a protective film;
transferring at an atmosphere the substrate on which the protective film is formed; and
removing the protective film from the substrate that has been transferred at the atmosphere.

2. The method according to claim 1, wherein forming the protective film is performed at the atmosphere.

3. The method according to claim 1, wherein forming the protective film is performed in a vacuum.

4. The method according to claim 1, wherein removing the protective film is performed in a vacuum.

5. The method according to claim 4, further including, after removing the protective film, forming a film on the substrate in a vacuum without exposing the substrate to an atmosphere.

6. The method according to claim 1, wherein removing the protective film is performed at the atmosphere.

7. The method according to claim 6, further including, after removing the protective film, forming a film on the substrate at the atmosphere.

8. The method according to claim 7, wherein in forming the film, the film is formed by a plating method.

9. The method according to claim 1, further including, before forming the protective film, removing an oxide generated on the substrate.

10. The method according to claim 9, wherein removing the oxide is performed at the atmosphere.

11. The method according to claim 10, wherein removing the oxide includes removing the oxide with a chemical solution containing hydrogen fluoride (HF).

12. The method according to claim 9, wherein removing the oxide is performed in a vacuum.

13. The method according to claim 12, wherein removing the oxide includes:
supplying a mixed gas containing a gas containing a halogen element and a basic gas to the substrate to transform the oxide to generate a reaction product; and
removing the reaction product.

14. The method according to claim 1, wherein a physical property of the ionic liquid changes depending on an environmental factor.

15. The method according to claim 14, wherein the environmental factor includes temperature.

16. The method according to claim 14, wherein the physical property includes at least one of viscosity and adhesiveness.

17. The method according to claim 1, wherein the ionic liquid has a property of not evaporating in a vacuum.

18. The method according to claim 1, wherein the substrate has a region where a conductive material is exposed on a surface.

19. A semiconductor manufacturing device comprising:
a first processing module configured to apply a liquid material containing an ionic liquid on a substrate to form a protective film;
a second processing module configured to remove the protective film formed on the substrate; and
a transfer module configured to transfer at an atmosphere the substrate between the first processing module and the second processing module.

20. A system comprising:
a first processing device configured to apply a liquid material containing an ionic liquid on a substrate to form a protective film;
a second processing device configured to remove the protective film formed on the substrate; and
a transfer device configured to transfer at an atmosphere the substrate between the first processing device and the second processing device.
